(19) United States
(12) Patent Application Publication
(10) Pub. No.: US 2025/0183183 A1
(43) Pub. Date: Jun. 5, 2025

(54) SIP MODULE WITH STILTED INTERCONNECTS

(71) Applicant: Qorvo US, Inc., Greensboro, NC (US)

(72) Inventors: Kelly M. Lear, Longwood, FL (US); Jeffrey Miller, Allen, TX (US); Deepukumar M. Nair, Lake Mary, FL (US)

(21) Appl. No.: 18/945,681

(22) Filed: Nov. 13, 2024

Related U.S. Application Data
(60) Provisional application No. 63/604,550, filed on Nov. 30, 2023.

(51) Int. Cl. H01L 23/538; H01L 23/36; H01L 25/10

(52) U.S. Cl. CPC H01L 23/5385; H01L 25/105; H01L 23/36

(57) ABSTRACT

The present disclosure relates to a system in package (SIP) with stilted interconnects to enable top-side and/or dual-side cooling and to accommodate large surface mounted components in a double-sided configuration. The SIP includes a laminate substrate, at least one electrical component formed at a bottom surface of the laminate substrate, and at least one bottom stilted interconnect connected to and protruding from the bottom surface of the laminate substrate. Herein, the at least one bottom stilted interconnect includes a number of dielectric sections and a conductive structure extending vertically through the dielectric sections. The conductive structure includes a number of conductors and a number of metal plates. Each conductor extends vertically through a corresponding dielectric section, and the metal plates alternate with the conductors in a vertical direction. The at least one first electrical component is electrically and/or thermally coupled to the at least one bottom stilted interconnect.

### RELATED APPLICATIONS

This application claims the benefit of provisional patent application Ser. No. 63/604,550, filed Nov. 30, 2023, the disclosure of which is hereby incorporated herein by reference in its entirety.

### FIELD OF THE DISCLOSURE

The present disclosure relates to a system in package (SIP) with stilted interconnects to enable top-side and/or dual-side cooling and to accommodate large surface mounted components in a double-sided configuration.

### BACKGROUND

High power performance and high computing performance in micro-scale applications, such as radio frequency (RF) semiconductor devices, poses many challenges in meeting ever demanding requirements. As power demands increase, the complexity in managing thermal waste generated by the RF semiconductor devices has increased significantly. If the heat generated by the

RF semiconductor devices cannot be dissipated efficiently, the RF semiconductor devices may fail to operate or have a degraded operating performance.

In traditionally constructed laminate overmolded system in package (SIP) modules, it is difficult to utilize a top-side of the SIP module for cooling, especially for wire-bond dies in the modules, and it is difficult to build in double-sided configurations with large surface mounted components (e.g., on a bottom-side of one SIP module), such as capacitors, inductors, or other large passive components, which are often necessary for higher power modules and often required to be placed close to active devices for higher frequency modules. With a conventional land grid array (LGA) or ball grid array (BGA), the SIP modules may only provide bottom-side cooling and bottom side input/output (I/O) connections, and leave limited space for components mounted on the bottom-side of the SIP module.

Accordingly, there remains a need for improved SIP module designs to enable top-side cooling or dual-side cooling for devices within the SIP module while maintaining high power capable interconnects. In addition, there is also a need for improved SIP module designs capable of accommodating large surface mounted components in double-sided configurations.

### SUMMARY

The present disclosure relates to a system in package (SIP) with stilted interconnects to enable top-side and/or dual-side cooling and to accommodate large surface mounted components in a double-sided configuration. The disclosed SIP includes a first laminate substrate, at least one first electrical component formed at a bottom surface of the first laminate substrate, and at least one bottom stilted interconnect connected to and protruding from the bottom surface of the first laminate substrate. Herein, the at least one bottom stilted interconnect includes a number of dielectric sections and at least one conductive structure extending vertically through the dielectric sections. Each of the at least one conductive structure includes a number of conductors and a number of metal plates. Each conductor extends vertically through a corresponding one of the dielectric sections, and the metal plates alternate with the conductors in a vertical direction. The at least one first electrical component is electrically and/or thermally coupled to the at least one bottom stilted interconnect.

In one embodiment of the SIP, one of the dielectric sections includes a section protrusion, which extends horizontally beyond certain ones of the dielectric sections and has an exposed surface not covered by the certain ones of the dielectric sections. One of the metal plates includes a plate protrusion that is formed on the exposed surface of the section protrusion. The at least one first electrical component is coupled to the at least one bottom stilted interconnect at the plate protrusion.

In one embodiment of the SIP, the at least one bottom stilted interconnect has a three-dimensional (3D) ring shape and is located about a periphery of the bottom surface of the first laminate substrate.

In one embodiment of the SIP, the at least one bottom stilted interconnect has a closed 3D ring shape.

In one embodiment of the SIP, the at least one bottom stilted interconnect has an open 3D ring shape with one or more openings. Each opening extends vertically through the dielectric sections.

In one embodiment of the SIP, the at least one conductive structure comprises a number of conductive structures, each of which extends vertically through the dielectric sections. The conductive structures are placed in a row or an array.

In one embodiment of the SIP, each of the conductors has a diameter between 50 μm and 1600 μm. A total height of the at least one bottom stilted interconnect is between 250 μm and 5000 μm.

In one embodiment of the SIP, the at least one bottom stilted interconnect further includes two spread conductive structures closely surrounding the at least one conductive structure. Herein, each spread conductive structure extends vertically through the dielectric sections and is coupled to ground. The at least one conductive structure is configured to transmit electrical signals, while the two spread conductive structures are configured to maintain a characteristic impedance of the at least one conductive structure at a certain value.

In one embodiment of the SIP, the at least one conductive structure and the two spread conductive structures are configured to provide a first metal-plate pitch at a top side of the at least one bottom stilted interconnect, and a second metal-plate pitch at a bottom side of the at least one bottom stilted interconnect, where the first metal-plate pitch is finer than the second metal-plate pitch. The top side of the at least one bottom stilted interconnect faces the bottom surface of the first laminate substrate.

In one embodiment of the SIP, the at least one bottom stilted interconnect further includes one or more expanded conductive structures next to the at least one conductive structure. Herein, each of the one or more expanded conductive structures extends vertically through the dielectric sections. Each of the one or more expanded conductive structures includes a number of conductors, each of which vertically extends through a corresponding one of the dielectric sections, and a number of metal plates that alternate with the conductors in a vertical direction. The conductors within each of the one or more expanded conductive structures are not vertically aligned with each other, and a combination of the at least one conductive structure and the one or more expanded conductive structures provides different metal-plate pitches at the top side and the bottom side of the at least one bottom stilted interconnect.

In one embodiment of the SIP, the at least one first electrical component is one of a wire-bond die, a flip-chip die, a surface mounted device (SMD) and a chiplet.

According to one embodiment, the SIP further includes a mold compound formed on the bottom surface of the first laminate substrate to at least encapsulate sides of the at least one first electronic component and to encapsulate sides of the at least one bottom stilted interconnect.

In one embodiment of the SIP, the first laminate substrate includes a number of dielectric layers and at least one heatsink stanchion extending vertically through the dielectric layers. The at least one first electrical component is vertically aligned with and thermally coupled to the at least one heatsink stanchion, such that heat generated by the at least one first electrical component is eligible to be dissipated through the at least one heatsink stanchion to achieve top-side cooling.

In one embodiment of the SIP, the at least one bottom stilted interconnect is thermally coupled to the at least one first electrical component, such that the heat generated by the at least one first electrical component is eligible to be dissipated through both the at least one heatsink stanchion and the at least one bottom stilted interconnect to achieve dual-side cooling.

According to one embodiment, the SIP further includes a heatsink spreader over a top surface of the first laminate substrate and thermally coupled to the at least one heatsink stanchion.

According to one embodiment, the SIP further includes at least one second electrical component formed on the top surface of the first laminate substrate, which is one of a wire-bond die, a flip-chip die, an SMD, and a chiplet.

According to one embodiment, the SIP further includes at least one top stilted interconnect connected to the top surface of the first laminate substrate. Herein, the at least one top stilted interconnect includes a number of dielectric sections and at least one conductive structure extending vertically through the dielectric sections. The at least one conductive structure of the at least one top stilted interconnect includes a number of metal plates and a number of conductors vertically aligned with each other. Herein, each of the conductors extends vertically through a corresponding one of the dielectric sections, and the metal plates alternate with the conductors in a vertical direction. At least one of the at least one first electrical component and the at least one second electrical component is electrically and/or thermally coupled to the at least one top stilted interconnect.

According to one embodiment, the SIP further includes a mold compound formed on the top surface of the first laminate substrate to at least encapsulate sides of the at least one second electronic component and to encapsulate sides of the at least one top stilted interconnect.

According to one embodiment, the SIP further includes a second laminate substrate located underneath the first laminate substrate and connected to the first laminate substrate through the at least one bottom stilted interconnect.

According to one embodiment, the SIP further includes at least one third electrical component formed on a top surface of the second laminate substrate, which is one of a wire-bond die, a flip-chip die, an SMD, and a chiplet.

According to one embodiment, a communication device includes a control system, a baseband processor, receive circuitry, and transmit circuitry. At least one or any combination of the control system, the baseband processer, the transmit circuitry, and the receive circuitry is implemented in a SIP module, which includes a first laminate substrate, at least one first electrical component, and at least one bottom stilted interconnect. Herein, the at least one first electrical component is formed at a bottom surface of the first laminate substrate. The at least one bottom stilted interconnect is connected to and protrudes from the bottom surface of the first laminate substrate. The at least one bottom stilted interconnect includes a number of dielectric sections and at least one conductive structure extending vertically through the dielectric sections. Each of the at least one conductive structure includes a number of conductors and a number of metal plates. Each conductor extends vertically through a corresponding one of the dielectric sections, and the metal plates alternate with the conductors in a vertical direction. The at least one first electrical component is electrically and/or thermally coupled to the at least one bottom stilted interconnect.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIGS. 1A-1F illustrate an exemplary stilted interconnect according to some embodiments of the present disclosure.

FIGS. 2A-5C illustrate alternative configurations of the stilted interconnect according to some embodiments of the present disclosure.

FIG. 6 illustrates a simplified block diagram of a system in package (SIP) module with one or more stilted interconnects according to some embodiments of the present disclosure.

FIGS. 7-17 illustrate different implementations of the SIP module shown in FIG. 6.

FIG. 18 illustrates a block diagram of a communication device that includes at least one SIP module shown in FIGS. 6-17 according to some embodiments of the present disclosure.

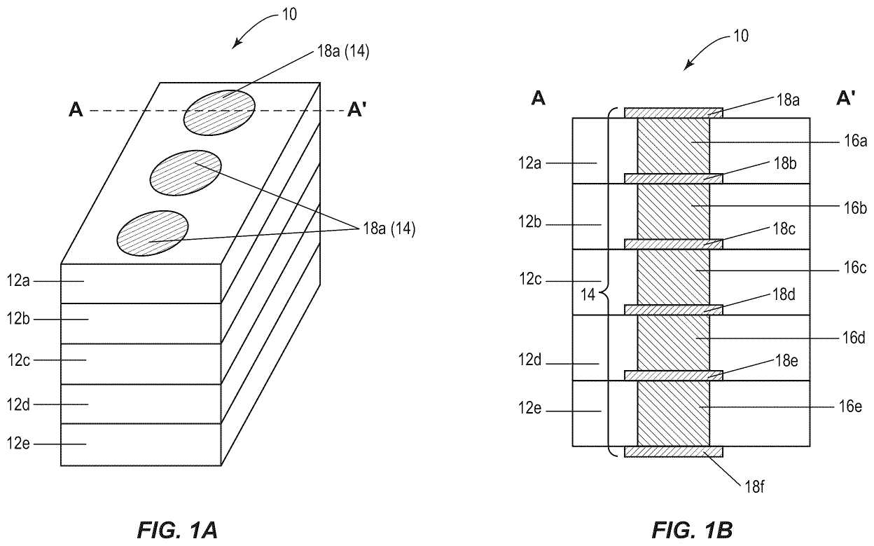

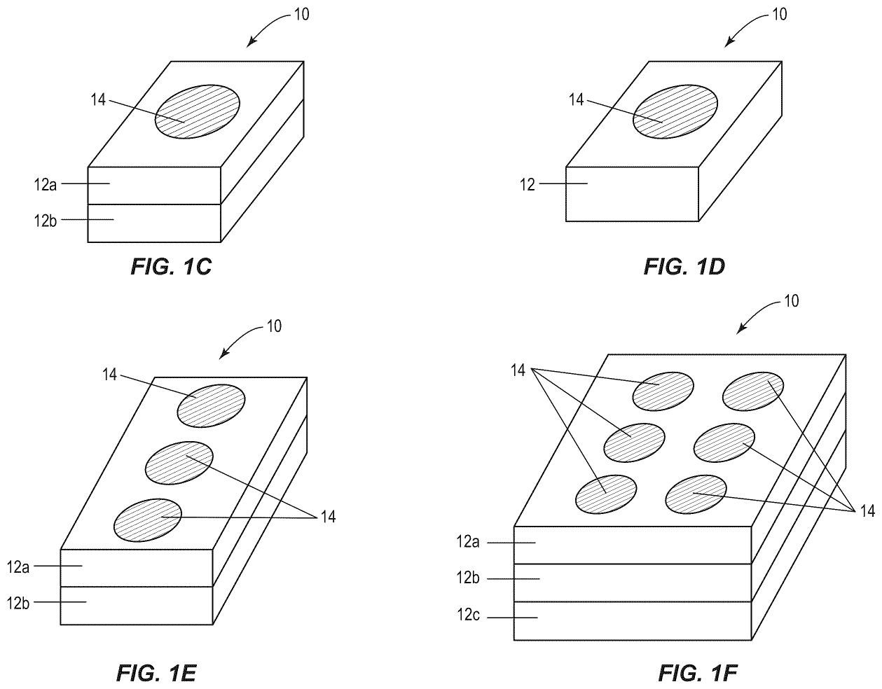

It will be understood that for clear illustrations, FIGS. 1A-18 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

In traditionally constructed laminate overmolded system in package (SIP) modules, it is difficult to utilize a top-side of the SIP modules for cooling (especially for wire-bond dies in the modules) and difficult to build double-sided configurations with large surface mounted components (especially on a bottom-side of the module), which, however, are often necessary for higher power modules. With a conventional land grid array (LGA) or ball grid array (BGA), the SIP modules may be limited to bottom-side cooling and a small space for bottom-side component-mounting. Herein, stilted interconnects are proposed for SIP module designs, so as to enable top-side and/or dual-side cooling and to accommodate large surface mounted components in a double-sided configuration.

FIGS. 1A and 1B illustrate an exemplary stilted interconnect 10 according to some embodiments of the present disclosure. FIG. 1A shows a three-dimensional (3D) view of the stilted interconnect 10, while FIG. 1B shows a cross-section view along a dashed line A-A′ in FIG. 1A. For the purposes of this illustration, the stilted interconnect 10 includes five dielectric sections 12 (e.g., a first dielectric section 12a, a second dielectric section 12b underneath the first dielectric section 12a, a third dielectric section 12c underneath the second dielectric section 12b, a fourth dielectric section 12d underneath the third dielectric section 12c, and a fifth dielectric section 12e underneath the fourth dielectric section 12d) and three conductive structures 14 extending vertically through the dielectric sections 12. The three conductive structures 14 may be placed in a row. Herein, each conductive structure 14 includes five conductors 16 vertically aligned with each other, and six metal plates 18, which alternate with the five conductors 16 in a vertical direction. In some embodiments, a first metal plate 18a is formed at a top of the first dielectric section 12a, a second metal plate 18b is formed at a top of the second dielectric section 12b, a third metal plate 18c is formed at a top of the third dielectric section 12c, a fourth metal plate 18d is formed at a top of the fourth dielectric section 12d, a fifth metal plate 18e is formed at a top of the fifth dielectric section 12e, and a sixth metal plate 18f is formed at a bottom of the fifth dielectric section 12e. In addition, a first conductor 16a extends through the first dielectric section 12a and connects the first metal plate 18a and the second metal plate 18b, a second conductor 16b extends through the second dielectric section 12b and connects the second metal plate 18b and the third metal plate 18c, a third conductor 16c extends through the third dielectric section 12c and connects the third metal plate 18c and the fourth metal plate 18d, a fourth conductor 16d extends through the fourth dielectric section 12d and connects the fourth metal plate 18d and the fifth metal plate 18e, and a fifth conductor 16e extends through the fifth dielectric section 12e and connects the fifth metal plate 18e and the sixth metal plate 18f. As such, each conductive structure 14 can provide an electrical/thermal path from the first metal plate 18a to the sixth metal plate 18f. Each dielectric section 12 may be formed of an insulating material (e.g., FR-4, polyimide, BT, etc.) or a semi-insulating material (e.g., Semi-insulating GaAs, Semi-insulating Silicon Carbide, etc.) with a thickness between 10 μm and 5 mm, the conductors 16 may be formed as plated vias or coined inserts, and the metal plates 18 may be formed of a metal material, such as copper.

In some embodiments, each dielectric section 12 may have a same thickness and a same size/shape, each conductor 16 may have a same thickness and a same size/shape, and each metal plate 18 may have a same thickness and a same size/shape. In different applications, the stilted interconnect 10 may include fewer or more dielectric sections 12 (e.g., one to twenty dielectric sections 12), fewer or more conductive structures 14 extending through the dielectric sections 12 with a different layout, and the conductive structures 14 may have different sizes and shapes. In addition, each conductive structure 14 may include fewer or more conductors 16 and fewer or more metal plates according to the number of the dielectric sections 12. Furthermore, the dielectric sections 12 may have different thicknesses and/or different sizes/shapes, the conductors 16 may have different thicknesses and/or different sizes/shapes, and the metal plates 18 may have different thicknesses and/or different sizes/shapes. FIGS. 1C-1E show non-limiting examples of variations. FIG. 1C illustrates the stilted interconnect 10 that includes two dielectric sections 12 with one large conductive structure 14 extending vertically through the two dielectric sections 12. FIG. 1D illustrates the stilted interconnect 10 that includes one thick dielectric section 12 with one large conductive structure 14 extending vertically through the dielectric section 12. FIG. 1E illustrates the stilted interconnect 10 that includes two dielectric sections 12 with three conductive structures 14 that are placed in a row and extend vertically through the two dielectric sections 12. FIG. 1F illustrates the stilted interconnect 10 that includes three dielectric sections 12 with six conductive structures 14 that are placed in a 2×3 configuration and extend vertically through the three dielectric sections 12. Typically, each conductor 16 has a diameter between 50 μm and 1600 μm, which has a greater cross section than a conventional wire-bond and allows for higher power I/Os. A total height of the stilted interconnect 10 may be between 250 μm and 5000 μm.

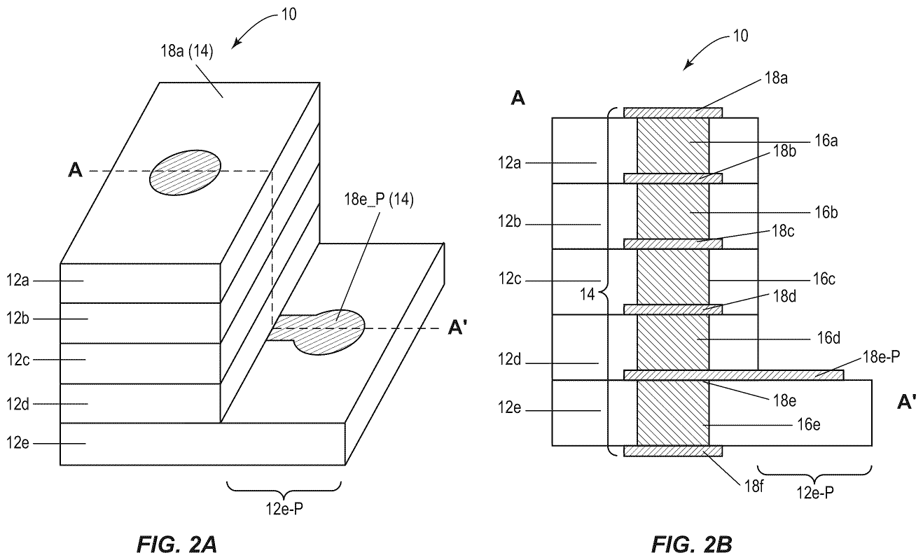

In some embodiments, the conductive structure 14 within the stilted interconnect 10 may provide more than one electrical/thermal path. As illustrated in FIGS. 2A and 2B, the fifth dielectric section 12e has a larger size than the upper dielectric sections 12a-12d to provide a section protrusion 12e-P with a top surface not covered by the upper dielectric sections 12a-12d, and the fifth metal plate 18e extends horizontally beyond the upper dielectric sections 12a-12d to provide a plate protrusion 18e-P that is exposed on the top surface of the section protrusion 12e-P. As such, the conductive structure 14 can provide a first electrical/thermal path from the first metal plate 18a to the sixth metal plate 18f, and a second electrical/thermal path from the first metal plate 18a to the plate protrusion 18e-P of the fifth metal plate 18e.

In different applications, another dielectric section 12 instead of the fifth dielectric section 12e may have a section protrusion, and accordingly, another metal plate 18 instead of the fifth metal plate 18e may have a plate protrusion. In addition, more than one dielectric section may include section protrusions, and these section protrusions may have a same size or different sizes (e.g., the dielectric sections 12 have a stepped configuration: the fifth dielectric section 12e has a large size section protrusion, the fourth dielectric section 12d has a mid-size section protrusion, and the third dielectric section 12c has a small size section protrusion). Accordingly, more than one metal plate 18 may have plate protrusions exposed on the corresponding section protrusions, respectively (if the section protrusions have different sizes) or one metal plate 18 may have a plate protrusion exposed on a very top one of the section protrusions (if the section protrusions have the same size).

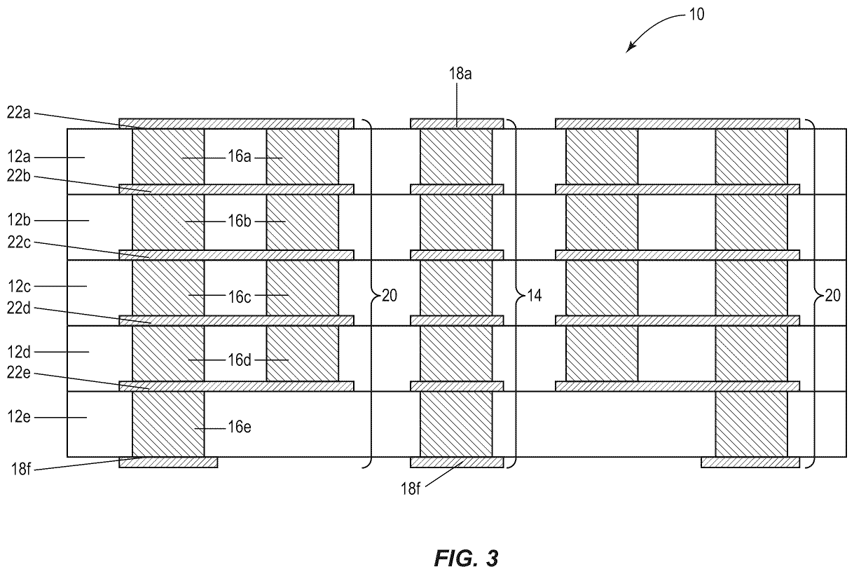

For radio frequency (RF) applications, impedance matching is a fundamental requirement for circuit designs. In some embodiments, the stilted interconnect 10 may be configured to provide an internal ground structure to maintain proper characteristic impedance (e.g., 50 Ω or 75 Ω I/O impedance) for RF I/Os, as illustrated in FIG. 3. For the purpose of this illustration, besides one conductive structure 14, the stilted interconnect 10 may further include two spread conductive structures 20. Herein, the conductive structure 14 may be configured to transmit RF signals (i.e., functioning as an RF I/O), while the spread conductive structures 20 closely surround the conductive structure 14 (no other conductive component in between) and may be electrically coupled to ground. As such the characteristic impedance of the center conductive structure 14 can be maintained at a proper value.

In some cases, the stilted interconnect 10 is used to connect devices (e.g., with fine pitch) within a SIP module to a next level assembly (e.g., with a coarse pitch), so the stilted interconnect 10 may also be desired to provide fan-out functionality. For a non-limiting example, each spread conductive structure 20 includes two first conductors 16a extending vertically through the first dielectric section 12a, two second conductors 16b extending vertically through the second dielectric section 12b, two third conductors 16c extending vertically through the third dielectric section 12c, two fourth conductors 16d extending vertically through the fourth dielectric section 12d, and one fifth conductor 16e extending vertically through the fifth dielectric section 12e. Correspondingly, each spread conductive structure 20 includes five spread metal plates 22 and one metal plate 18f. A first spread metal plate 22a is formed at the top of the first dielectric section 12a and connects top surfaces of the two first conductors 16a, a second spread metal plate 22b is formed at the top of the second dielectric section 12b and connects bottom surfaces of the two first conductors 16a and top surfaces of the two second conductors 16b, a third spread metal plate 22c is formed at the top of the third dielectric section 12c and connects bottom surfaces of the two second conductors 16b and top surfaces of the two third conductors 16c, a fourth spread metal plate 22d is formed at the top of the fourth dielectric section 12d and connects bottom surfaces of the two third conductors 16c and top surfaces of the two fourth conductors 16d, a fifth spread metal plate 22e is formed at the top of the fifth dielectric section 12e and connects bottom surfaces of the two fourth conductors 16d and a top surface of the fifth conductor 16e, and the sixth metal plate 18f is formed at the bottom of the fifth dielectric section 12e and connects to a bottom surface of the fifth conductor 16e. Herein, the number of conductor(s) extending vertically through the bottom dielectric layer 12 (e.g., one fifth conductor 16e extending vertically through the fifth dielectric layer 12e) may be smaller than the number of conductor(s) extending vertically through the top dielectric layer 12 (e.g., two first conductors 16a extending vertically through the first dielectric layer 12d). In addition, horizontal space between the first spread metal plate 22a of each spread conductive structure 20 and the first metal plate 18a of the center conductive structure 14 is smaller than a horizontal space between the sixth metal plate 18f of each spread conductive structure 20 and the sixth metal plate 18f of the center conductive structure 14 to achieve fan-out functionality.

In different applications, the stilted interconnect 10 may include fewer or more spread conductive structures 20 placed closely to the conductive structure 14, and the spread conductive structure(s) 20 may or may not be coupled to ground (e.g., the spread conductive structure 20 is used for RF signal transmission, while the conductive structure 14 is coupled to ground). Each spread conductive structure 20 may include more conductors extending vertically through each of certain dielectric sections 12, and these conductors are connected by corresponding spread metal plate(s) 22.

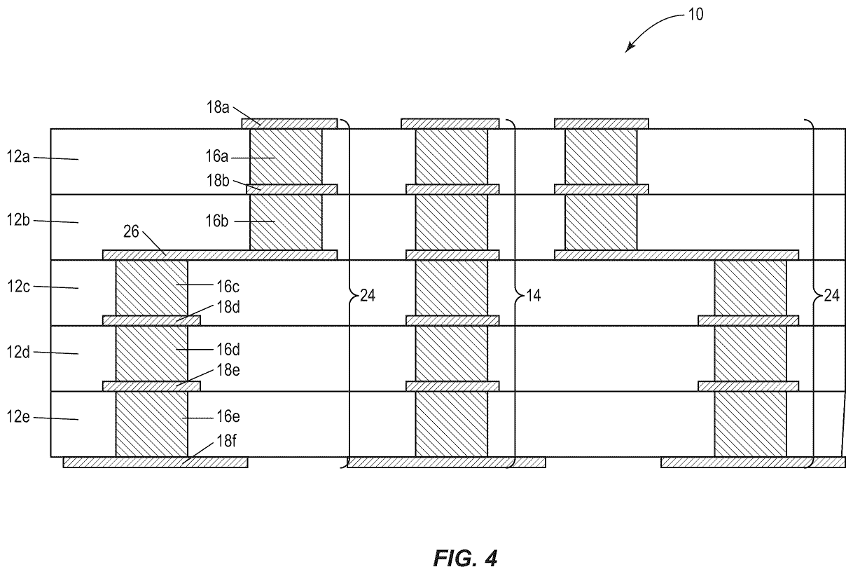

FIG. 4 shows an alternative configuration of the stilted interconnect 10 for achieving redistribution/fan-out. For the purpose of this illustration, besides one conductive structure 14, the stilted interconnect 10 may further include two expanded conductive structures 24 next to the conductive structure 14. Each expanded conductive structure 24 still includes conductors 16 extending vertically through corresponding dielectric sections 12, however, the conductors 16 may not be vertically aligned with each other (e.g., the first conductor 16a is vertically aligned with the second conductor 16b, the third conductor 16c, the fourth conductor 16d, and the fifth conductor 16e are vertically aligned with each other, but the first conductor 16a and the second conductor 16b are offset from the remaining third, fourth and fifth conductors 16c-16e). Correspondingly, besides the metal plates 18 (e.g., the first metal plate 18a is formed at the top of the first dielectric section 12a and connects to a top surface of the first conductor 16a, the second metal plate 18b is formed at the top of the second dielectric section 12b and connects a bottom surface of the first conductor 16a and a top surface of the second conductor 16b, the fourth metal plate 18d is formed at the top of the fourth dielectric section 12d and connects a bottom surface of the third conductor 16c and a top surface of the fourth conductor 16d, the fifth metal plate 18e is formed at the top of the fifth dielectric section 12e and connects a bottom surface of the fourth conductor 16d and a top surface of the fifth conductor 16e, and the sixth metal plate 18f is formed at the bottom of the fifth dielectric section 12e and connects to a bottom surface of the fifth conductor 16e), each expanded conductive structure 24 may also include one or more expanded metal plates 26 to connect adjacent conductors 16 that are offset from each other. In this illustration, the expanded metal plate 26 is formed at the top of the third dielectric section 12c and connects a bottom surface of the second conductor 16b to a top surface of the third conductor 16c. Herein, a horizontal space between the first metal plate 18a of each expanded conductive structure 24 and the first metal plate 18a of the conductive structure 14 is smaller than a horizontal space between the sixth metal plate 18f of each expanded conductive structure 24 and the sixth metal plate 18f of the conductive structure 14 to achieve a fan-out functionality. In different applications, the stilted interconnect 10 may include fewer or more expanded conductive structures 24, which may have an identical expanded configuration (e.g., extending a same horizontal scope) or a different expanded configuration (e.g., extending different horizontal scopes). In addition, each expanded conductive structure 24 may include more than one offset structure among the conductors 16 (e.g., the third conductor 16c is horizontally offset from the first and the second conductors 16a-16b, and the fourth and the fifth conductors 16d-16e are further horizontally offset from the third conductor 16c) with more than one expanded metal plate for connection (not shown).

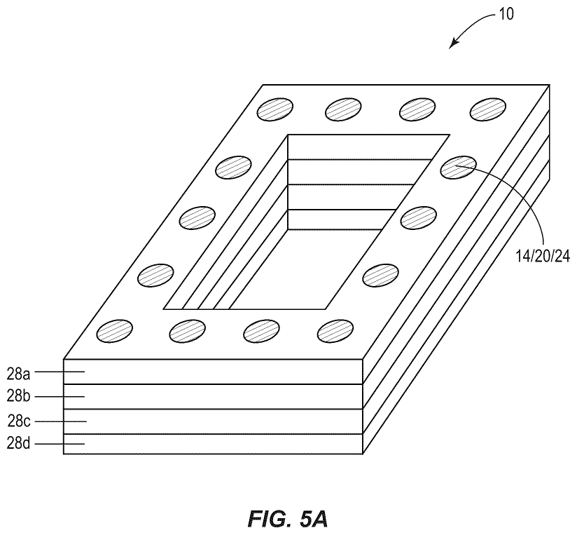

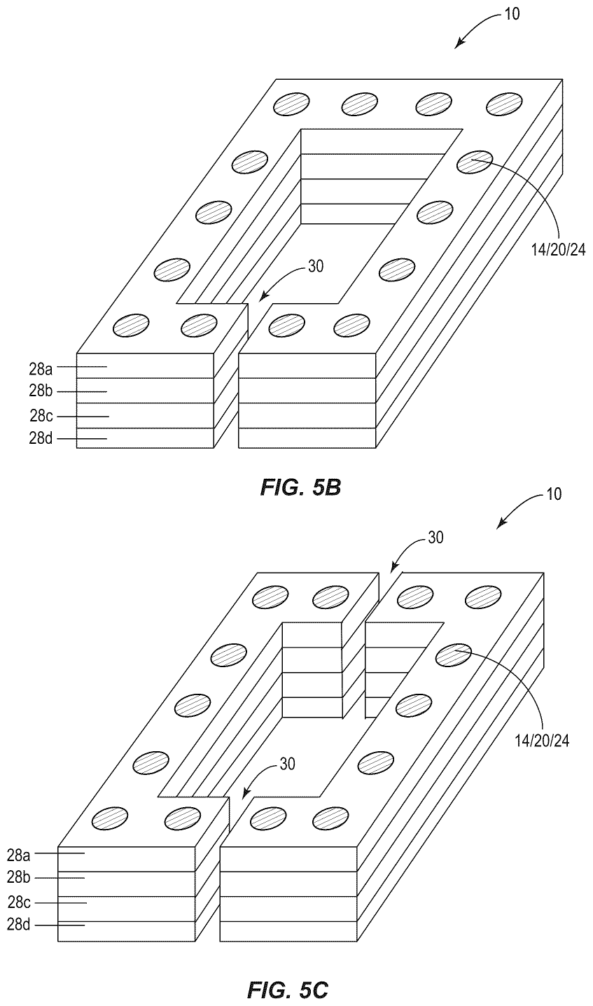

As shown in FIGS. 1A-4, the stilted interconnect 10 has a columnar shape, and in some cases, the stilted interconnect 10 may have a 3D ring shape as shown in FIGS. 5A-5C. As illustrated in FIG. 5A, the stilted interconnect 10 has a closed 3D ring shape. Herein, the stilted interconnect 10 includes four dielectric layers 28 (e.g., a first dielectric layer 28a, a second dielectric layer 28b underneath the first dielectric layer 28a, a third dielectric layer 28c underneath the second dielectric layer 28b, and a fourth dielectric layer 28d underneath the third dielectric layer 28c), each of which has a closed ring shape. Similar to the dielectric sections 12, each dielectric layer 28 may be formed of an insulating material or a semi-insulating material (each dielectric layer 28 is a continuous or lengthy version of one dielectric section 12).

In addition, the stilted interconnect 10 may include fourteen conductive structures 14/20/24 (i.e., any combination of the conductive structures 14, the spread conductive structures 20, and the expanded conductive structures 24, shown in FIGS. 1A-4) dispersed in the closed 3D ring configuration, and each conductive structure 14/20/24 extends vertically through the dielectric layers 28. When the stilted interconnect 10 includes one or more conductive structures 14 as shown in FIGS. 2A and 2B, the dielectric layers 28 may have different ring shapes (e.g., the fourth dielectric layer 28 may have a smaller inner circle than the remaining first, second, and third dielectric layers 28a-28c to accommodate one or more plate protrusions (similar to the plate protrusion 18e-P). In different applications, the stilted interconnect 10 may include fewer or more dielectric layers 28 and/or fewer or more conductive structures 14/20/24 extending vertically through the dielectric layers 28.

In some embodiments, the stilted interconnect 10 has an open 3D ring shape with one opening 30, as illustrated in FIG. 5B. Herein, the opening 30 extends vertically through all the dielectric layers 28, and accordingly, each dielectric layer 28 has an open ring shape instead of a closed ring shape. In some embodiments, the stilted interconnect 10 may have an open 3D ring shape with two or more openings 30, as illustrated in FIG. 5C. For the purpose of this illustration, the two openings 30 have the same size and are located at opposite sides of the stilted interconnect 10, and each opening 30 extends vertically through all the dielectric layers 28. In different applications, the stilted interconnect 10 may include more openings 30 with a different layout within the stilted interconnect 10.

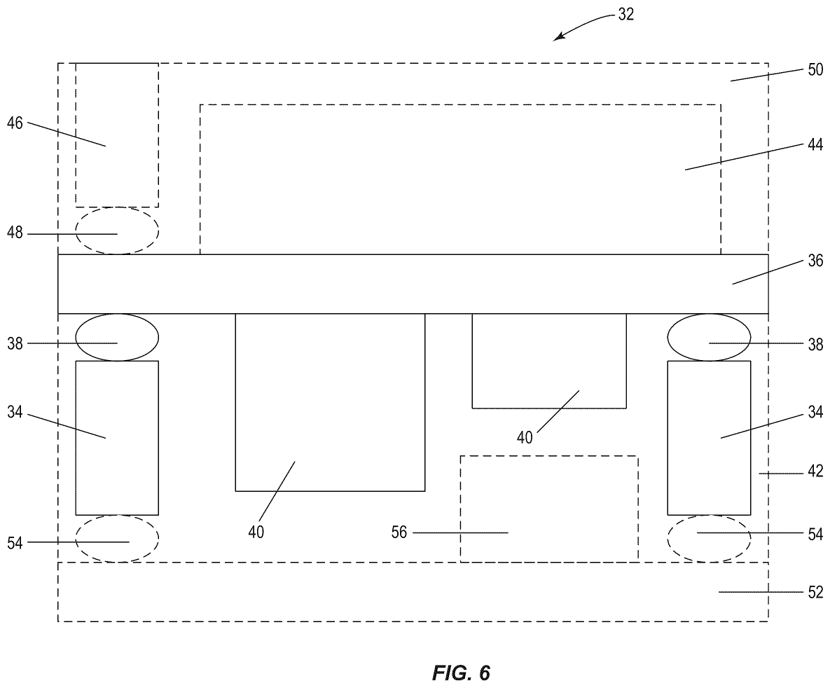

FIG. 6 illustrates a simplified block diagram of a system in package (SIP) module 32 with one or more stilted interconnects. In some embodiments, the SIP module 32 includes a first laminate substrate 36, one or more bottom stilted interconnects 34 connected to a bottom surface of the first laminate substrate 36 via one or more first connecting elements 38 (only two bottom stilted interconnects 34 and two first connecting elements 38 are shown for simplicity), and one or more first electronic components 40 (only two first electronic components 40 are shown for simplicity). Herein, each bottom stilted interconnect 34 may be any one of the stilted interconnects 10 shown in FIGS. 1A-4 (e.g., the bottom stilted interconnects 34 may have a same configuration or different configurations), may be a portion of the stilted interconnect 10 shown in FIGS. 5A-5C (i.e., a cross-section view of the 3D ring shaped stilted interconnect 10 shown in FIGS. 5A-5C), or any one of the stilted interconnects 10 described above. Each bottom stilted interconnect 34 is connected to the first laminate substrate 36 in a manner similar to a surface mounted device (SMD). Typically, the one or more bottom stilted interconnects 34 may be located about a periphery of the bottom surface of the first laminate substrate 36. The first connecting elements 38 may be solder balls, solder paste based components, conductive epoxy, sintered materials, or the like, and are configured to connect the bottom stilted interconnects 34 to the first laminate substrate 36. The one or more first electronic components 40 are attached to the bottom surface of the first laminate substrate 36 and may be surrounded by the one or more bottom stilted interconnects 34. Each first electronic component 40 may be one of a wire-bond die, a flip-chip die, an SMD (e.g., an active SMD, or a passive component, such as a capacitor, an inductor, and a resistor), and etc., and may be connected to the one or more bottom stilted interconnects 34 by bonding wires (not shown), metal layers in the first laminate substrate 36 (not shown), and/or other conductive means (e.g. the first connecting elements 38).

Since each bottom stilted interconnect 34 has a relatively large height and protrudes from the bottom surface of the first laminate substrate 36, the first electronic components 40 attached to the bottom surface of the first laminate substrate 36 have a relatively large flexibility in size/height (e.g., a tall/large first electronic component 40, and especially a tall/large passive component can be accommodated). For a non-limiting example, large bypass capacitors can be placed close to a high-power die and on the bottom surface of the first laminate substrate 36 to achieve a desired electrical performance. Typically, a bottom side of the SIP module 32 is attached to a next level assembly, such that without the tall bottom stilted interconnects 34 (e.g., using standard short solder balls), a tall/large first electronic component 40 may be directly attached to the next level assembly and cause damage. In some applications, a first mold compound 42 may be applied over the bottom surface of the first laminate substrate 36 to at least encapsulate sides of each first electronic component 40 and to encapsulate sides of each bottom stilted interconnect 34 (i.e., a bottom of each bottom stilted interconnect 34 is not covered by the first mold compound 42 and exposed for next-level packaging, not shown). In some applications, the first mold compound 42 is omitted, and the one or more bottom stilted interconnects 34 and the one or more first electronic components 40 are exposed to air. In some applications, the one or more bottom stilted interconnects 34 may be located at an inner portion of the bottom surface of the first laminate substrate 36. In addition to signal and thermal paths, the one or more bottom stilted interconnects 34 may also provide mechanical support to the SIP module 32.

In some embodiments, the SIP module 32 may have a double-sided configuration and further include one or more second electronic components 44 (only one second electronic component 44 is shown for simplicity) formed on a top surface of the first laminate substrate 36. Further, there might be one or more top stilted interconnects 46 connected to the top surface of the first laminate substrate 36 via one or more second connecting elements 48 (only one top stilted interconnect 46 and one second connecting element 48 are shown for simplicity). Similar to the bottom stilted interconnect(s) 34, each top stilted interconnect 46 may also be any one of the stilted interconnects 10 shown in FIGS. 1A-4 or may be a portion of the stilted interconnect 10 shown in FIGS. 5A-5C. The one or more top stilted interconnects 46 may be located about a periphery of the top surface of the first laminate substrate 36 and are connected to the first laminate substrate 36 in a manner similar to an SMD. The second connecting elements 48 may be solder balls, solder paste based components, conductive epoxy, sintered materials, or the like, and are configured to connect the top stilted interconnects 46 to the first laminate substrate 36. Each second electronic component 44 may be one of a wire-bond die, a flip-chip die, an SMD (e.g., an active SMD, or a passive component, such as a capacitor, an inductor, and a resistor), and etc.

Each top stilted interconnect 46 may have a relatively large height and may protrude upwards from the top surface of the first laminate substrate 36, such that the second electronic components 44 attached to the top surface of the first laminate substrate 36 may have a relatively large flexibility in size/height (e.g., a tall/large second electronic component 44, and especially a tall/large passive component can be accommodated). For a non-limiting example, large bypass capacitors can be placed close to a high-power die and on the top surface of the first laminate substrate 36 to achieve a desired electrical performance. Without the tall top stilted interconnects 46, when a top side of the SIP module 32 is attached to a next level assembly, the tall/large second electronic component 44 may be directly attached to the next level assembly and cause damage.

Herein, the one or more first electronic components 40, the one or more second electronic components 44, the one or more bottom stilted interconnects 34, and the one or more top stilted interconnects 46 may be connected to each other by bonding wires (not shown), metal layers in the first laminate substrate 36 (not shown), and/or other conductive means (e.g. the first connecting elements 38, the second connecting element 48). In some applications, a second mold compound 50 may be applied over the top surface of the first laminate substrate 36 to encapsulate at least sides of each second electronic component 44 and sides of each top stilted interconnect 46 (e.g., a top of each top stilted interconnect 46 is not covered by the second mold compound 50 and exposed for connecting a heatsink spreader or next-level packaging, not shown). In some applications, the second mold compound 50 is omitted, and the one or more second electronic components 44 and the one or more top stilted interconnects 46 may be exposed to air.

In some embodiments, the SIP module 32 may further include a second laminate substrate 52 to accommodate more electronic components. The second laminate substrate 52 is located underneath the first laminate substrate 36 and connected to the first laminate substrate 36 through the one or more bottom stilted interconnects 34, which may also provide mechanical support between the first and second laminate substrates 36 and 52. Herein, each bottom stilted interconnect 34 is connected to a top surface of the second laminate substrate 52 via one or more third connecting elements 54 (only two third connecting elements 54 are shown for simplicity). The third connecting elements 54 may be solder balls, solder paste based components, conductive epoxy, sintered materials, or the like, and are configured to connect the bottom stilted interconnects 34 to the second laminate substrate 52. There might be one or more third electronic components 56 (only one third electronic component 56 is shown for simplicity) formed on a top surface of the second laminate substrate 52. Each third electronic component 56 may be one of a wire-bond die, a flip-chip die, an SMD (e.g., an active SMD, or a passive component, such as a capacitor, an inductor, and a resistor), and etc., and may be connected to the one or more bottom stilted interconnects 34 by bonding wires (not shown), metal layers in the second laminate substrate 52 (not shown), and/or other conductive means (e.g. the third connecting elements 54). In some applications, the first mold compound 42 may fill a gap between the bottom surface of the first laminate substrate 36 and the top surface of the second laminate substrate 52 and encapsulate each first electronic component 40, each bottom stilted interconnect 34, and each third electronic component 56. In some applications, the first mold compound 42 is omitted, and the one or more first electronic components 40, the one or more bottom stilted interconnects 34, and the one or more third electronic components 56 are exposed to air.

Note that the one or more bottom stilted interconnects 34 might be configured to transmit electrical signals from the first electronic components 40 and/or second electronic components 44 to the next level package assembly (on the bottom side of the SIP module 32), configured to transmit electrical signals among the first, second, and third electronic components 40, 44, and 56 (if they exist), and/or configured to be grounded. In addition, the one or more bottom stilted interconnects 34 might be configured to conduct heat generated by the first, second, and/or third electronic components 40, 44, and/or 56 (if they exist). The one or more top stilted interconnects 46, on the other hand might be configured to transmit electrical signals from the first electronic components 40, the second electronic components 44, and/or the third electronic components 56 (if they exist) to the next level package assembly (on the top side of the SIP module 32), configured to be grounded, and/or configured to conduct heat generated by the first, second, and/or third electronic components 40, 44, and/or 56 (if they exist).

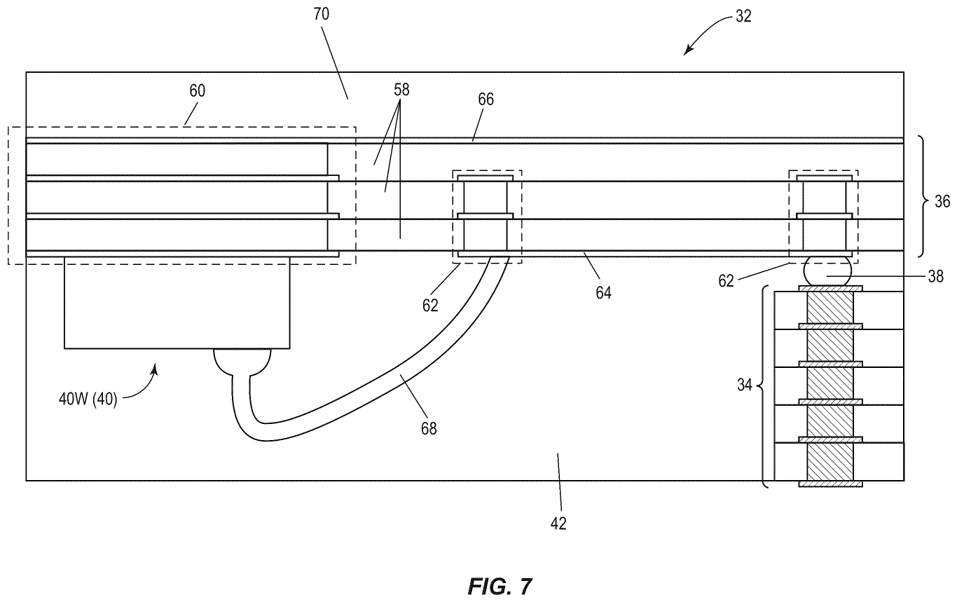

FIGS. 7-17 illustrate different implementations of the SIP module 32 shown in FIG. 6. FIG. 7 shows a portion of the SIP module 32, which includes the first laminate substrate 36, the bottom stilted interconnect 34 connected to the bottom surface of the first laminate substrate 36 via the first connecting element 38, and the first electronic component 40. Herein, the bottom stilted interconnect 34 may be the stilted interconnect 10 shown in FIGS. 1A-1F, any one of the stilted interconnects 10 described with respect to FIGS. 1A-1F, a portion of the stilted interconnect 10 shown in FIGS. 5A-5C, or a portion of any one stilted interconnect 10 described with respect to FIGS. 5A-5C. The bottom stilted interconnect 34 is connected to the first laminate substrate 36 in a manner similar to an SMD and may be located about the periphery of the bottom surface of the first laminate substrate 36.

In this illustration, the first laminate substrate 36 includes three dielectric layers 58, a heatsink stanchion 60 that extends vertically through the dielectric layers 58, and two via structures 62 that are connected with each other by a metal trace 64 at the bottom surface of the first laminate substrate 36 and extend vertically within the dielectric layers 58 (further details on the heatsink stanchion 60 and the via structure 62 can be found in U.S. utility patent application Ser. No. 17/538,583, filed Nov. 30, 2021, and titled SYSTEM IN PACKAGE WITH FLIP CHIP DIE OVER MULTI-LAYER HEATSINK STANCHION, which is incorporated herein by reference). The first laminate substrate 36 may further include a top metal layer 66, which covers the top surface of the first laminate substrate 36 and serves as a ground plane. In different applications, the first laminate substrate 36 may include fewer or more dielectric layers 58, no or more heatsink stanchions 60, and more via structures 62 with different connection configurations.

The first electronic component 40 is a wire-bond die 40W with multiple bonding wires 68 (only one bonding wire 68 is shown for simplicity). The wire-bond die 40W is attached to the bottom surface of the first laminate substrate 36 and is vertically aligned with and thermally coupled to the heatsink stanchion 60 within the first laminate substrate 36. As such, heat generated by the wire-bond die 40W can be dissipated through the heatsink stanchion 60 to achieve top-side cooling. In addition, the wire-bond die 40W is electrically coupled to the metal trace 64 through one bonding wire 68 and the bottom stilted interconnect 34 is electrically coupled to the metal trace 64 through the first connecting element 38. Accordingly, the wire-bond die 40W is electrically coupled to the bottom stilted interconnect 34, and the bottom stilted interconnect 34 may serve as an I/O of the SIP module 32 and may provide a signal path for the wire-bond die 40W to a next level assembly (not shown).

In some embodiments, the SIP module 32 may further include the first mold compound 42 applied over the bottom surface of the first laminate substrate 36 to fully encapsulate the wire-bond die 40W and to encapsulate sides of the bottom stilted interconnect 34, where a bottom (e.g., the sixth metal plate 18f) of the bottom stilted interconnect 34 is not covered by the first mold compound 42 and exposed for next-level packaging (not shown). In some embodiments, the SIP module 32 may further include a heatsink spreader 70 formed over the top surface of the first laminate substrate 36. The heatsink spreader 70 may be comprised of copper (Cu) pillars, gold (Au), and or an alloy such as molybdenum copper (CuMo). The heatsink spreader 70 may be in contact with the heatsink stanchion 60.

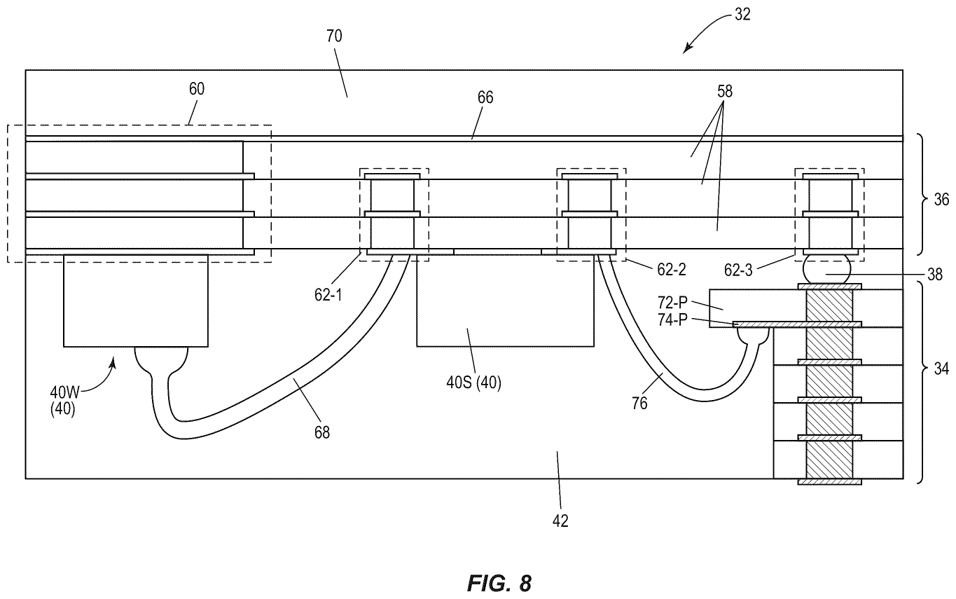

In some applications, besides the wire-bond die 40W, the SIP module 32 may also include other one or more first electronic components 40. FIG. 8 shows a portion of the SIP module 32, which includes the first laminate substrate 36, the bottom stilted interconnect 34 connected to the bottom surface of the first laminate substrate 36 via the first connecting element 38, the wire-bond die 40W, and another first electronic component 40. Herein, the bottom stilted interconnect 34 may be the stilted interconnect 10 shown in FIGS. 2A-2B, any one of the stilted interconnects 10 described with respect to FIGS. 2A-2B, a portion of the stilted interconnect 10 shown in FIGS. 5A-5C, or a portion of any one of the stilted interconnects 10 described with respect to FIGS. 5A-5C, which includes a section protrusion 72-P (similar to the section protrusion 12e-P shown in FIG. 2B) and a plate protrusion 74-P (similar to the plate protrusion 18e-P shown in FIG. 2B) on a bottom surface of the section protrusion 72-P. The bottom stilted interconnect 34 is still connected to the first laminate substrate 36 in a manner similar to an SMD and may be located about the periphery of the bottom surface of the first laminate substrate 36.

In this illustration, the first laminate substrate 36 includes the three dielectric layers 58, the heatsink stanchion 60, the top metal layer 66, and three via structures 62 (e.g., a first via structure 62-1, a second via structure 62-2, and a third via structure 62-3) extending vertically within the dielectric layers 58. The first, second, and third via structures 62-1, 62-2, and 62-3 are separate from each other. In different applications, the first laminate substrate 36 may include fewer or more dielectric layers 58, no or more heatsink stanchions 60, and more via structures 62 with different connection configurations.

The other first electronic component 40 is an SMD 40S sitting on and electrically connected to both the first and second via structures 62-1 and 62-2. The wire-bond die 40W is electrically coupled to the first via structure 62-1 through the bonding wire 68. The plate protrusion 74-P of the bottom stilted interconnect 34 is electrically coupled to the second via structure 62-2 through a second bonding wire 76. In addition, the bottom stilted interconnect 34 is also connected to the third via structure 62-3 through the first connecting element 38. Accordingly, the bottom stilted interconnect 34 is electrically coupled to the SMD 40S and may be further connected to another component (embedded in the first laminate substrate 36, or on the bottom surface of the first laminate substrate 36, not shown) through the third via structure 62-3. The bottom stilted interconnect 34 may serve as an I/O of the SIP module 32 and may provide a signal path for the SMD 40S to a next level assembly (not shown). In some embodiments, the SIP module 32 may further include the first mold compound 42 applied over the bottom surface of the first laminate substrate 36 to fully encapsulate the wire-bond die 40W and the SMD 40S, and to encapsulate sides of the bottom stilted interconnect 34, where a bottom (e.g., the sixth metal plate 18f) of the bottom stilted interconnect 34 is not covered by the first mold compound 42 and exposed for next-level packaging (not shown). In some embodiments, the SIP module 32 may further include the heatsink spreader 70 formed over the top surface of the first laminate substrate 36, which may be in contact with the heatsink stanchion 60.

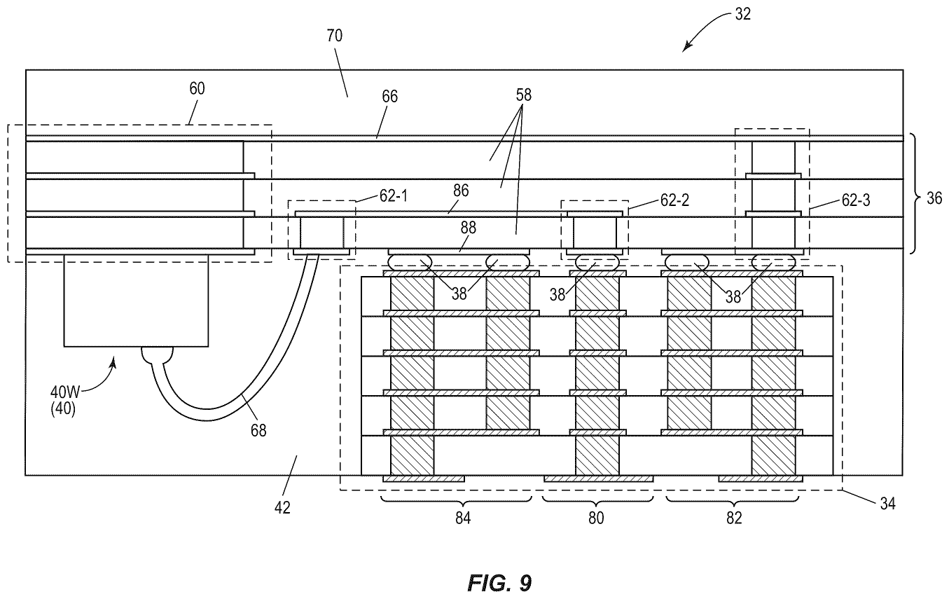

FIG. 9 illustrates a portion of the SIP module 32 with the bottom stilted interconnect 34, which may be the stilted interconnect 10 shown in FIG. 3, any one of the stilted interconnects 10 described with respect to FIG. 3, a portion of the stilted interconnect 10 shown in FIGS. 5A-5C, or a portion of any one of the stilted interconnects 10 described with respect to FIGS. 5A-5C. In detail, the bottom stilted interconnect 34 includes a first conductive structure 80 (similar to the conductive structure 14 shown in FIG. 3), a second conductive structure 82 (similar to one spread conductive structure 20 shown in the FIG. 3), and a third conductive structure 84 (similar to one of the spread conductive structures 20 shown in FIG. 3). The first conductive structure 80 is surrounded by the second and third conductive structures 82 and 84, and these three conductive structures 80-84 are configured to provide a fine metal-plate pitch at the top of the bottom stilted interconnect 34 and a coarse metal-plate pitch at the bottom of the bottom stilted interconnect 34. The bottom stilted interconnect 34 is still connected to the first laminate substrate 36 in a manner similar to an SMD and may be located about the periphery of the bottom surface of the first laminate substrate 36.

In this illustration, the first laminate substrate 36 includes the three dielectric layers 58, the heatsink stanchion 60 that extends vertically through the dielectric layers 58, and the three via structures 62 (e.g., a first via structure 62-1, a second via structure 62-2, and a third via structure 62-3). The first via structure 62-1 and the second via structure 62-2 extend vertically within the dielectric layers 58 and are connected with each other by an inner metal trace 86 within the dielectric layers 58. The third via structure 62-3 extends vertically through the dielectric layers 58, is in contact with the top metal layer 66, and is separate from the first and second via structures 62-1 and 62-2. The first laminate substrate 36 may further include the top metal layer 66, which covers the top surface of the first laminate substrate 36 and serves as a ground plane. In different applications, the first laminate substrate 36 may include fewer or more dielectric layers 58, no or more heatsink stanchions 60, and more via structures 62 with different connection configurations.

The wire-bond die 40W is attached to the bottom surface of the first laminate substrate 36 and is vertically aligned with and thermally coupled to the heatsink stanchion 60 within the first laminate substrate 36. As such, heat generated by the wire-bond die 40W can be dissipated through the heatsink stanchion 60 to achieve top-side cooling. In addition, the wire-bond die 40W is electrically coupled to the first via structure 62-1 through one bonding wire 68.

The first conductive structure 80 of the bottom stilted interconnect 34 is electrically coupled to the second via structure 62-2 through one first connecting element 38. As such, the wire-bond die 40W is electrically connected to the first conductive structure 80 of the bottom stilted interconnect 34 through the bonding wire 68, the first via structure 62-1, the inner metal trace 86, the second via structure 62-2, and the first connecting element 38. The second conductive structure 82 of the bottom stilted interconnect 34 is electrically coupled to the third via structure 62-3 through two first connecting elements 38. As such, the second conductive structure 82 is electrically connected to the grounded top metal layer 66 through the third via structure 62-3 and the first connecting elements 38. Furthermore, the third conductive structure 84 of the bottom stilted interconnect 34 is electrically coupled to a surface metal layer 88, which is formed on the bottom surface of the first laminate substrate 36, through two first connecting elements 38. Herein, the surface metal layer 88 is electrically coupled to ground (not shown), and thus the third conductive structure 84 of the bottom stilted interconnect 34 is grounded as well. Accordingly, the first conductive structure 80 of the bottom stilted interconnect 34 may serve as an I/O of the SIP module 32 and may provide a signal path for the wire-bond die 40W to a next level assembly (not shown). On the other hand, the grounded second and third conductive structures 82 and 84 help to maintain the characteristic impedance of the first conductive structure 80 at a proper value (e.g., 500 or 750), especially for RF applications. In some embodiments, the SIP module 32 may further include the first mold compound 42 applied over the bottom surface of the first laminate substrate 36 to fully encapsulate the wire-bond die 40W and to encapsulate sides of the bottom stilted interconnect 34, where each bottom of the first, second, and third conductive structures 80-84 is not covered by the first mold compound 42 and exposed for next-level packaging (not shown). In some embodiments, the SIP module 32 may further include the heatsink spreader 70 formed over the top surface of the first laminate substrate 36, and may be in contact with the heatsink stanchion 60 and the third via structure 62-3.

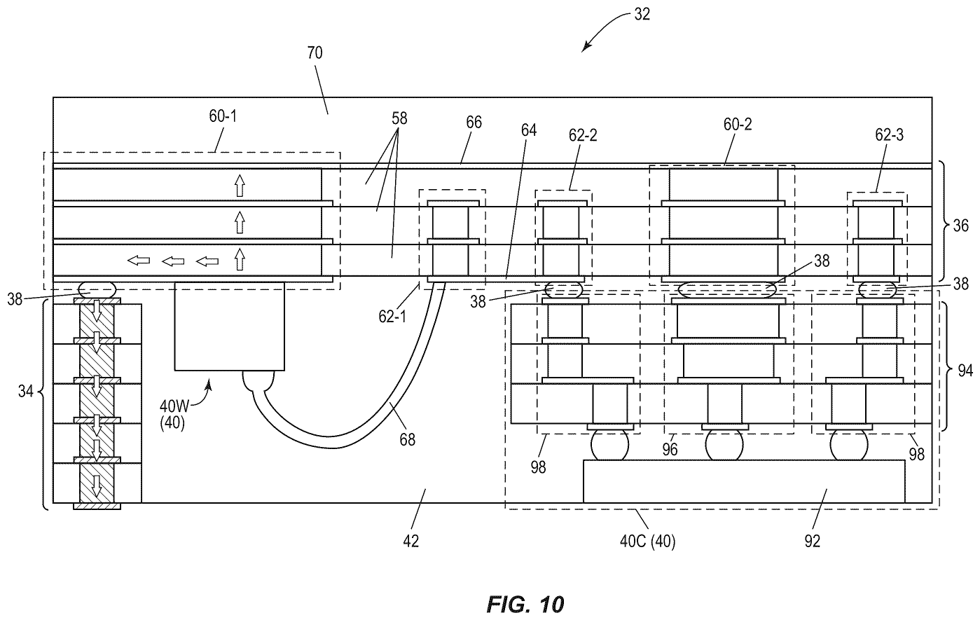

In some applications, one bottom stilted interconnect 34 may be configured to conduct heat without transmitting electrical signals. FIG. 10 shows a portion of the SIP module 32, which includes the first laminate substrate 36, the bottom stilted interconnect 34 connected to the bottom surface of the first laminate substrate 36 via the first connecting element 38, the wire-bond die 40W, and another first electronic component 40. Herein, the bottom stilted interconnect 34 may be the stilted interconnect 10 shown in FIGS. 1A-1F, any one of the stilted interconnects 10 described with respect to FIGS. 1A-1F, a portion of the stilted interconnect 10 shown in FIGS. 5A-5C, or a portion of any one of the stilted interconnects 10 described with respect to FIGS. 5A-5C. The bottom stilted interconnect 34 is connected to the first laminate substrate 36 in a manner similar to an SMD and may be located about the periphery of the bottom surface of the first laminate substrate 36 or located at an inner portion of the bottom surface of the first laminate substrate 36.

In this illustration, the first laminate substrate 36 includes three dielectric layers 58, two heatsink stanchions 60 (e.g., a first heatsink stanchion 60-1, and a second heatsink stanchion 60-2), and three via structures 62 (e.g., a first via structure 62-1, a second via structure 62-2, and a third via structure 62-3). Each heatsink stanchion 60 extends vertically through the dielectric layers 58. The first via structure 62-1 and the second via structure 62-2 extend vertically within the dielectric layers 58 and are connected with each other by the metal trace 64 at the bottom surface of the first laminate substrate 36. The third via structure 62-3 also extends vertically within the dielectric layers 58 and is separate from the first and second via structures 62-1 and 62-2. The first laminate substrate 36 may further include the top metal layer 66, which covers the top surface of the first laminate substrate 36 and serves as a ground plane. In different applications, the first laminate substrate 36 may include fewer or more dielectric layers 58, fewer or more heatsink stanchions 60, and more via structures 62 with different connection configurations.

The wire-bond die 40W is attached to the bottom surface of the first laminate substrate 36 and is vertically aligned with and thermally coupled to the first heatsink stanchion 60-1 within the first laminate substrate 36. The bottom stilted interconnect 34 is attached to the bottom surface of the first laminate substrate 36 and connected to the first heatsink stanchion 60-1 through the first connecting element 38. Accordingly, heat generated by the wire-bond die 40W can also be dissipated upward through the first heatsink stanchion 60-1 and dissipated downward through the bottom stilted interconnect 34 (via a portion of the first heatsink stanchion 60-1) to achieve dual-side cooling.

The other first electronic component 40 is a chiplet 40C that includes a flip-chip die 92 and a chip substrate 94 with one chip heatsink stanchion 96 and two chip via structures 98. The flip-chip die 92 is deposited on the chip substrate 94 and coupled to the chip heatsink stanchion 96 and the chip via structures 98. Herein, the chip heatsink stanchion 96 is configured to dissipate heat generated by the flip-chip die 92, while the chip via structures 98 are configured to transmit electrical signals from the flip-chip die 92 (further details on the chiplet 40C can be found in U.S. utility patent application Ser. No. 17/538,583, filed Nov. 30, 2021, and titled SYSTEM IN PACKAGE WITH FLIP CHIP DIE OVER MULTI-LAYER HEATSINK STANCHION, which is incorporated herein by reference).

The chip substrate 94 of the chiplet 40C is attached to the bottom surface of the first laminate substrate 36, where the chip heatsink stanchion 96 is coupled to the second heatsink stanchion 60-2 through one first connecting element 38, one chip via structure 98 is coupled to the second via structure 62-2 through one first connecting element 38, and the other chip via structure 98 is coupled to the third via structure 62-3 through one first connecting element 38. In addition, the wire-bond die 40W is electrically coupled to the first via structure 62-1 through the bonding wire 68. Since the first via structure 62-1 and the second via structure 62-2 are connected by the metal trace 64, the wire-bond die 40W is electrically coupled to the flip-chip die 92 of the chiplet 40C (signal I/Os are not shown in FIG. 10 for simplicity).

In some embodiments, the SIP module 32 may further include the first mold compound 42 applied over the bottom surface of the first laminate substrate 36 to fully encapsulate the wire-bond die 40W, at least encapsulate sides of the chiplet 40C (e.g., a backside of the flip-chip die 92 may be exposed through the first mold compound 42), and to encapsulate sides of the bottom stilted interconnect 34 (a bottom of the bottom stilted interconnect 34 is not covered by the first mold compound 42 and exposed for next-level packaging, not shown). In some embodiments, the SIP module 32 may further include the heatsink spreader 70 formed over the top surface of the first laminate substrate 36 and in contact with the first and second heatsink stanchions 60-1 and 60-2.

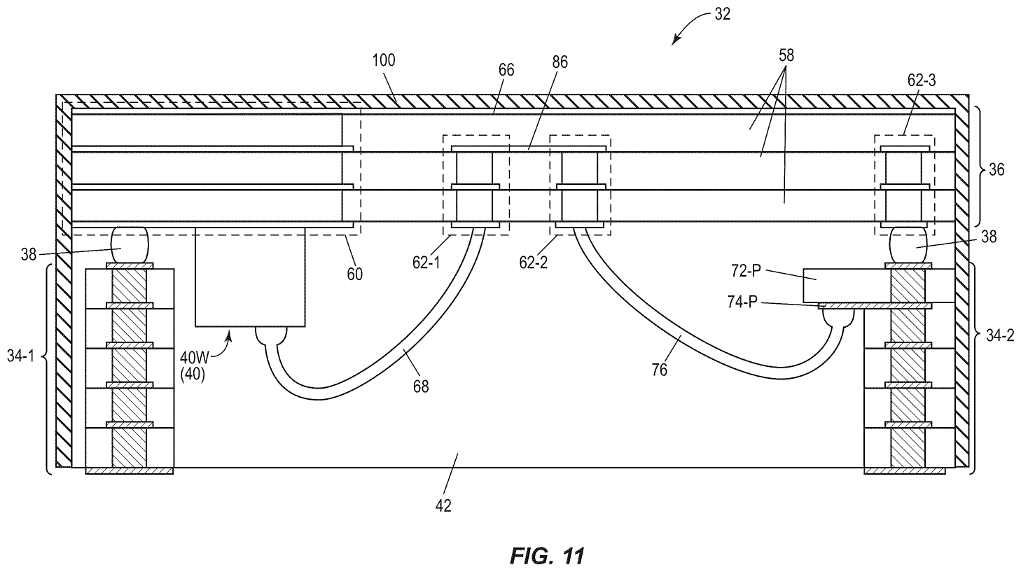

FIG. 11 shows a portion of the SIP module 32 with multiple bottom stilted interconnects 34 configured to conduct both heat and electrical signals. In this illustration, the SIP module 32 includes the first laminate substrate 36, two bottom stilted interconnects 34 (e.g., a first bottom stilted interconnect 34-1 and a second bottom stilted interconnect 34-2), and the wire-bond die 40W. Herein, the first bottom stilted interconnect 34-1 may be the stilted interconnect 10 shown in FIGS. 1A-1F, any one of the stilted interconnects 10 described with respect to FIGS. 1A-1F, a portion of the stilted interconnect 10 shown in FIGS. 5A-5C, or a portion of any one of the stilted interconnects 10 described with respect to FIGS. 5A-5C. The second bottom stilted interconnect 34-2 may be the stilted interconnect 10 shown in FIGS. 2A-2B, any one of the stilted interconnects 10 described with respect to FIGS. 2A-2B, a portion of the stilted interconnect 10 shown in FIGS. 5A-5C, or a portion of any one of the stilted interconnects 10 described with respect to FIGS. 5A-5C, which includes the section protrusion 72-P (similar to the section protrusion 12e-P shown in FIG. 2B) and the plate protrusion 74-P (similar to the plate protrusion 18e-P shown in FIG. 2B) on the bottom surface of the section protrusion 72-P. Each of the first and second bottom stilted interconnects 34-1 and 34-2 is connected to the first laminate substrate 36 in a manner similar to an SMD and may be located about the periphery of the bottom surface of the first laminate substrate 36.

Herein, the first laminate substrate 36 includes the three dielectric layers 58, the heatsink stanchion 60, the top metal layer 66, and the three via structures 62 (e.g., the first via structure 62-1, the second via structure 62-2, and the third via structure 62-3) extending vertically within the dielectric layers 58.

The first and second via structures 62-1 and 62-2 are connected to each other by the inner metal trace 86, and the third via structure 62-3 is separate from the first and second via structures 62-1 and 62-2. In different applications, the first laminate substrate 36 may include fewer or more dielectric layers 58, no or more heatsink stanchions 60, and more via structures 62 with different connection configurations.

The wire-bond die 40W is attached to the bottom surface of the first laminate substrate 36 and is vertically aligned with and thermally coupled to the heatsink stanchion 60 within the first laminate substrate 36. The first bottom stilted interconnect 34-1 is attached to the bottom surface of the first laminate substrate 36 and connected to the heatsink stanchion 60 through the first connecting element 38. Accordingly, heat generated by the wire-bond die 40W can also be dissipated upward through the heatsink stanchion 60 and dissipated downward through the bottom stilted interconnect 34 (via a portion of the heatsink stanchion 60) to achieve dual-side cooling. In addition, the wire-bond die 40W is electrically coupled to the first via structure 62-1 through the bonding wire 68. The plate protrusion 74-P of the second bottom stilted interconnect 34-2 is electrically coupled to the second via structure 62-2 through the second bonding wire 76. As such, the wire-bond die 40W is electrically coupled to the second bottom stilted interconnect 34-2 (through the bonding wire 68, the first via structure 62-1, the inner metal trace 86, the second via structure 62-2, and the second bonding wire 76), and the second bottom stilted interconnect 34-2 may serve as an I/O of the SIP module 32 and may provide a signal path for the wire-bond die 40W to a next level assembly (not shown). Furthermore, the second bottom stilted interconnect 34-2 is also connected to the third via structure 62-3 through the first connecting element 38, which may be connected to another component (embedded in the first laminate substrate 36, or on the bottom surface of the first laminate substrate 36, not shown).

In some embodiments, the SIP module 32 may further include the first mold compound 42 applied over the bottom surface of the first laminate substrate 36 to fully encapsulate the wire-bond die 40W, and to encapsulate sides of each bottom stilted interconnect 34, where a bottom of each bottom stilted interconnect 34 is not covered by the first mold compound 42 and exposed for next-level packaging (not shown). In some embodiments, the SIP module 32 may further include a shielding structure 100 that fully covers a top surface and side surfaces of the SIP module 32 without covering any portion of a bottom surface of the SIP module 32. If the top metal layer 66 exists and serves as a ground plane of the first laminate substrate 36, the shielding structure 100 may be in contact with the top metal layer 66 and coupled to ground.

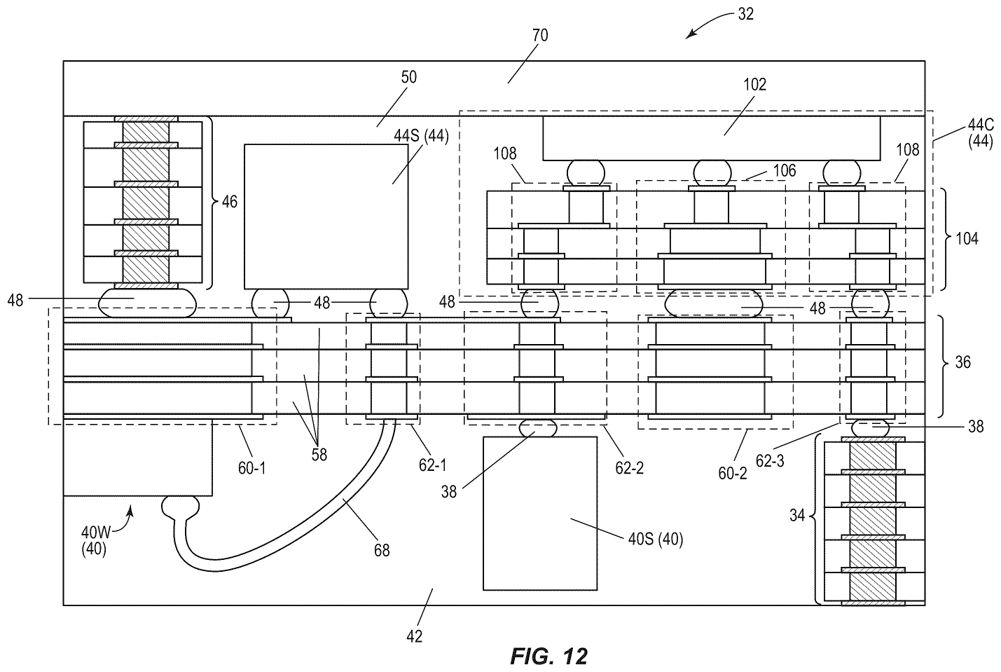

FIGS. 12-16 show the SIP module 32 that has a double-sided configuration and, besides the one or more first electronic components 40 attached to the bottom surface of the first laminate substrate 36, further includes one or more second electronic components 44 formed on the top surface of the first laminate substrate 36. FIG. 12 shows a portion of the SIP module 32, which includes the first laminate substrate 36, the bottom stilted interconnect 34, two first electronic components 40 (e.g., the wire-bond die 40W and the SMD 40S), the top stilted interconnect 46, and two second electronic components 44. Herein, each of the bottom stilted interconnect 34 and the top stilted interconnect 46 may be the stilted interconnect 10 shown in FIGS. 1A-4, any one of the stilted interconnects 10 described with respect to FIGS. 1A-4, a portion of the stilted interconnect 10 shown in FIGS. 5A-5C, or a portion of any one of the stilted interconnects 10 described with respect to FIGS. 5A-5C. The bottom stilted interconnect 34 may be the stilted interconnect 10 shown in FIGS. 1A-4, any one of the stilted interconnects 10 described with respect to FIGS. 1A-4, a portion of the stilted interconnect 10 shown in FIGS. 5A-5C, or a portion of any one of the stilted interconnects 10 described with respect to FIGS. 5A-5C. Each of the bottom stilted interconnect 34 and the top stilted interconnect 46 is connected to the first laminate substrate 36 in a manner similar to an SMD.

In this illustration, the first laminate substrate 36 includes the three dielectric layers 58, two heatsink stanchions 60 (e.g., a first heatsink stanchion 60-1, and a second heatsink stanchion 60-2), and three via structures 62 (e.g., a first via structure 62-1, a second via structure 62-2, and a third via structure 62-3). Each heatsink stanchion 60 extends vertically through the dielectric layers 58. The first, second, and third via structures 62-1, 62-2, and 62-3 are separate from each other, and each extends vertically through the dielectric layers 58. In different applications, the first laminate substrate 36 may include fewer or more dielectric layers 58, fewer or more heatsink stanchions 60, and more via structures 62 with different connection configurations, and certain via structures 62 may extend vertically within the dielectric layers 58 rather than extending vertically through the dielectric layers 58.

The bottom stilted interconnect 34 is coupled to the third via structure 62-3 at the bottom surface of the first laminate substrate 36 through the first connecting element 38. The top stilted interconnect 46 is coupled to the first heatsink stanchion 60-1 at the top surface of the first laminate substrate 36 through one second connecting element 48. The wire-bond die 40W is vertically aligned with and thermally coupled to the first heatsink stanchion 60-1 at the bottom surface of the first laminate substrate 36. As such, heat generated by the wire-bond die 40W can be dissipated through the first heatsink stanchion 60-1 and the top stilted interconnect 46 to achieve top-side cooling.

One second electronic component 44 is an SMD 44S, and another second electronic component 44 is a chiplet 44C (similar to the chiplet 40C described above) that includes a flip-chip die 102 and a chip substrate 104 with one chip heatsink stanchion 106 and two chip via structures 108. The flip-chip die 102 is deposited on the chip substrate 104 and coupled to the chip heatsink stanchion 106 and the chip via structures 108. Herein, the chip heatsink stanchion 106 is configured to dissipate heat generated by the flip-chip die 102, while the chip via structures 108 are configured to transmit electrical signals from the flip-chip die 102. The SMD 44S is connected to the first via structure 62-1 at the top surface of the first laminate substrate 36 through one second connecting element 48. The wire-bond die 40W is electrically coupled to the first via structure 62-1 at the bottom surface of the first laminate substrate 36 through one bonding wire 68. Accordingly, the wire-bond die 40W is electrically coupled to the SMD 44S. In some embodiments, the SMD 44S may further be connected to the first heatsink stanchion 60-1 at the top surface of the first laminate substrate 36 through one second connecting element 48 (or through a bonding wire, not shown). As such, heat generated by the SMD 44S can also be dissipated upward through a portion of the first heatsink stanchion 60-1 and the top stilted interconnect 46.

In addition, the SMD 40S is connected to the second via structure 62-2 at the bottom surface of the first laminate substrate 36 through one first connecting element 38. The chip substrate 104 of the chiplet 44C is attached to the top surface of the first laminate substrate 36, where the chip heatsink stanchion 106 is coupled to the second heatsink stanchion 60-2 at the top surface of the first laminate substrate 36 through one second connecting element 48, one chip via structure 108 is coupled to the second via structure 62-2 at the top surface of the first laminate substrate 36 through one second connecting element 48, and the other chip via structure 108 is coupled to the third via structure 62-3 at the top surface of the first laminate substrate 36 through one second connecting element 48. As such, the SMD 40S is electrically connected to the flip-chip die 102 of the chiplet 44C. Furthermore, since the bottom stilted interconnect 34 is coupled to the third via structure 62-3 at the bottom surface of the first laminate substrate 36, the flip-chip die 102 of the chiplet 44C is electrically connected to the bottom stilted interconnect 34. The bottom stilted interconnect 34 may serve as an I/O of the SIP module 32 and may provide a signal path for the chiplet 44C to a next level assembly (not shown). In some embodiments, the bottom stilted interconnect 34 may further be thermally coupled with the second heatsink stanchion 60-2 (not shown), and the bottom stilted interconnect 34 may also provide a thermal path for heat generated in the chiplet 44C.

In some embodiments, the SIP module 32 may further include the first mold compound 42 applied over the bottom surface of the first laminate substrate 36 to fully encapsulate the wire-bond die 40W and the SMD 40S, and to encapsulate sides of the bottom stilted interconnect 34 (a bottom of the bottom stilted interconnect 34 is not covered by the first mold compound 42 and exposed for next-level packaging, not shown). In some embodiments, the SIP module 32 may further include the second mold compound 50 applied over the top surface of the first laminate substrate 36 to fully encapsulate the SMD 44S, at least encapsulate sides of the chiplet 44C (e.g., a backside of the flip-chip die 102 may be exposed through the second mold compound 50), and to encapsulate sides of the top stilted interconnect 46 (a top of the top stilted interconnect 46 is not covered by the second mold compound 40). In some embodiments, the SIP module 32 may further include the heatsink spreader 70 that is formed over the second mold compound 50 (if it exists), and is in contact with the exposed top of the top stilted interconnect 46 and the backside of the flip-chip die 102.

Note that, when the bottom stilted interconnect 34 has a relatively large height, the SMD 40S attached to the bottom surface of the first laminate substrate 36 has a relatively large flexibility in size/height. In addition, the chip substrate 104 of the chiplet 44C helps to lift the flip-chip die 102 vertically beyond the SMD 44S and enables the backside of the flip-chip die 102 to be in contact with the heatsink spreader 70.

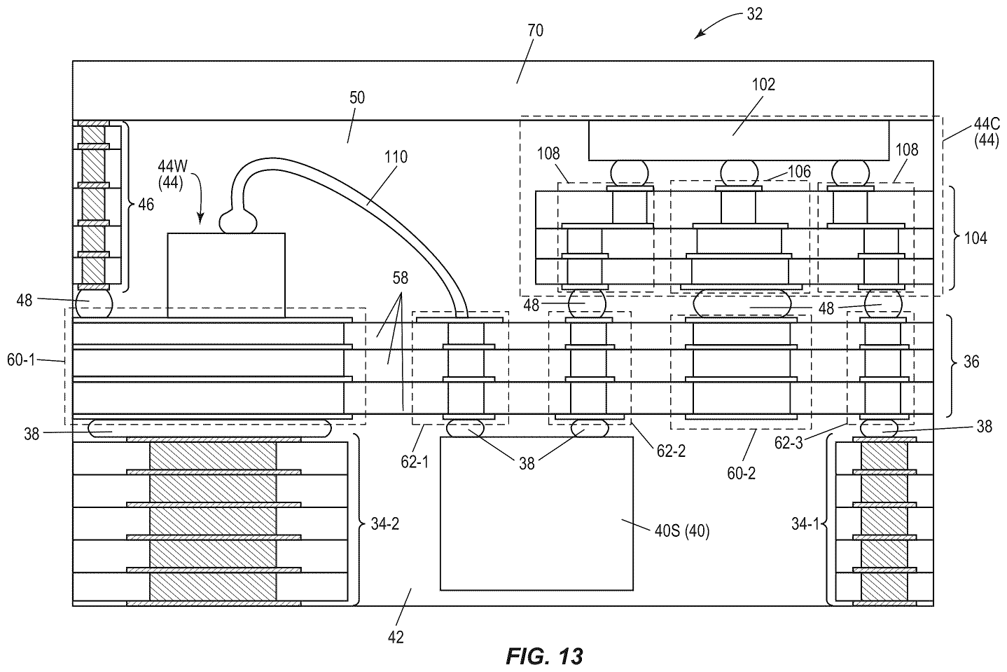

FIG. 13 shows a portion of the SIP module 32, which has a double-sided configuration and enables dual-side cooling. The SIP module 32 includes the first laminate substrate 36, two bottom stilted interconnects 34 (e.g., the first bottom stilted interconnect 34-1 and the second bottom stilted interconnects 34-2), one first electronic component 40 (e.g., the SMD 40S), the top stilted interconnect 46, and two second electronic components 44. Herein, each of the bottom stilted interconnects 34 and the top stilted interconnect 46 may be the stilted interconnect 10 shown in FIGS. 1A-4, any one of the stilted interconnects 10 described with respect to FIGS. 1A-4, a portion of the stilted interconnect 10 shown in FIGS. 5A-5C, or a portion of any one of the stilted interconnects 10 described with respect to FIGS. 5A-5C. The bottom stilted interconnect 34 may be the stilted interconnect 10 shown in FIGS. 1A-4, any one of the stilted interconnects 10 described with respect to FIGS. 1A-4, a portion of the stilted interconnect 10 shown in FIGS. 5A-5C, or a portion of any one of the stilted interconnects 10 described with respect to FIGS. 5A-5C. Each of the bottom stilted interconnects 34 and the top stilted interconnect 46 is connected to the first laminate substrate 36 in a manner similar to an SMD.

In this illustration, the first laminate substrate 36 still includes the three dielectric layers 58, two heatsink stanchions 60 (e.g., a first heatsink stanchion 60-1, and a second heatsink stanchion 60-2), and three via structures 62 (e.g., a first via structure 62-1, a second via structure 62-2, and a third via structure 62-3). Each heatsink stanchion 60 extends vertically through the dielectric layers 58. The first, second, and third via structures 62-1, 62-2, and 62-3 are separate from each other, and each extends vertically through the dielectric layers 58. In different applications, the first laminate substrate 36 may include fewer or more dielectric layers 58, fewer or more heatsink stanchions 60, and more via structures 62 with different connection configurations, and certain via structures 62 may extend vertically within the dielectric layers 58 rather than extending vertically through the dielectric layers 58.

The first bottom stilted interconnect 34-1 is coupled to the third via structure 62-3 at the bottom surface of the first laminate substrate 36 through one first connecting element 38. The second bottom stilted interconnect 34-2 is coupled to the first heatsink stanchion 60-1 at the bottom surface of the first laminate substrate 36 through one first connecting element 38. The top stilted interconnect 46 is coupled to the first heatsink stanchion 60-1 at the top surface of the first laminate substrate 36 through one second connecting element 48.

One second electronic component 44 is a wire-bond die 44W with multiple bonding wires 110 (only one bonding wire 110 is shown for simplicity), and another second electronic component 44 is the chiplet 44C. The wire-bond die 44W is vertically aligned with and thermally coupled to the first heatsink stanchion 60-1 at the top surface of the first laminate substrate 36. As such, heat generated by the wire-bond die 44W can be dissipated downward through the second bottom stilted interconnect 34-2 and can be dissipated upward through the top stilted interconnect 46, thereby achieving dual-side cooling. In addition, the wire-bond die 40W is electrically coupled to the first via structure 62-1 at the top surface of the first laminate substrate 36 through one bonding wire 110.

The SMD 40S is connected to the first and second via structures 62-1 and 62-2 at the bottom surface of the first laminate substrate 36 through two first connecting elements 38, respectively. As such, the SMD 40S is electrically coupled to the wire-bond die 44W through the first via structure 62-1. The chip substrate 104 of the chiplet 44C is attached to the top surface of the first laminate substrate 36, where the chip heatsink stanchion 106 is coupled to the second heatsink stanchion 60-2 at the top surface of the first laminate substrate 36 through one second connecting element 48, one chip via structure 108 is coupled to the second via structure 62-2 at the top surface of the first laminate substrate 36 through one second connecting element 48, and the other chip via structure 108 is coupled to the third via structure 62-3 at the top surface of the first laminate substrate 36 through one second connecting element 48. As such, the SMD 40S is electrically connected to the chiplet 44C/the flip-chip die 102 through the second via structure 62-2. Furthermore, since the first bottom stilted interconnect 34-1 is coupled to the third via structure 62-3 at the bottom surface of the first laminate substrate 36, the flip-chip die 102 of the chiplet 44C is electrically connected to the bottom stilted interconnect 34. The first bottom stilted interconnect 34-1 may serve as an I/O of the SIP module 32 and may provide a signal path for the chiplet 44C to a next level assembly (not shown). In some embodiments, the first bottom stilted interconnect 34-1 may further provide a thermal path for heat generated in the chiplet 44C.

In some embodiments, the SIP module 32 may further include the first mold compound 42 applied over the bottom surface of the first laminate substrate 36 to fully encapsulate the SMD 40S and to encapsulate sides of each bottom stilted interconnect 34, where a bottom of each bottom stilted interconnect 34 is not covered by the first mold compound 42 and exposed for next-level packaging (not shown). In some embodiments, the SIP module 32 may further include the second mold compound 50 applied over the top surface of the first laminate substrate 36 to fully encapsulate the wire-bond 44W, at least encapsulate sides of the chiplet 44C (e.g., the backside of the flip-chip die 102 may be exposed through the second mold compound 50), and to encapsulate sides of the top stilted interconnect 46 (the top of the top stilted interconnect 46 is not covered by the second mold compound 40). In some embodiments, the SIP module 32 may further include the heatsink spreader 70 that is formed over the second mold compound 50 (if it exists), and is in contact with the exposed top of the top stilted interconnect 46 and the backside of the flip-chip die 102.

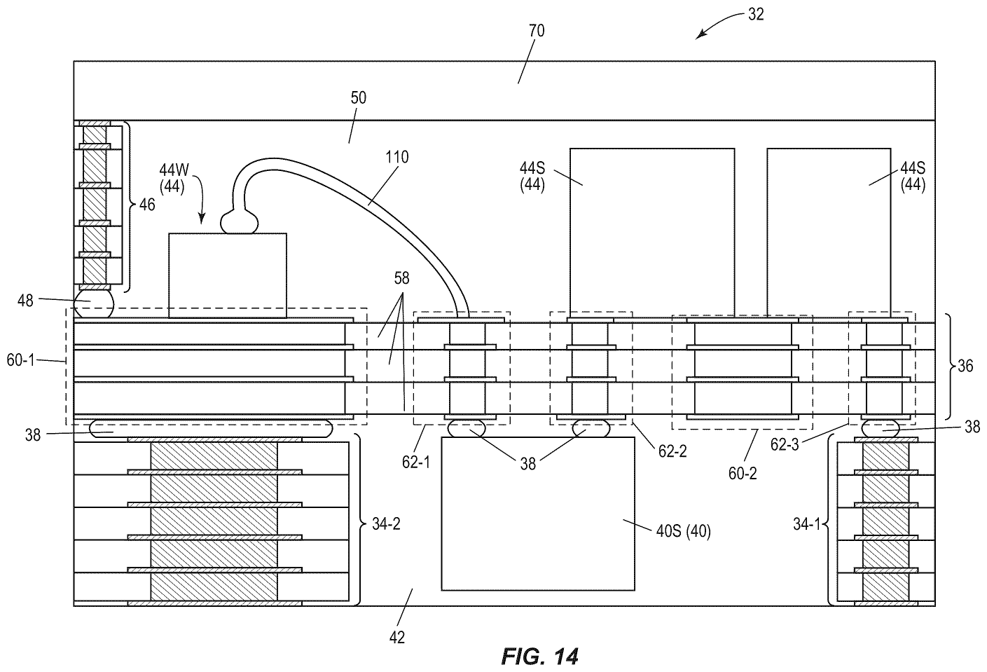

In different applications, the SIP module 32 may include fewer or more first electronic components 40 with different component types, and/or fewer or more second electronic components 44 with different component types. As illustrated in FIG. 14, within the SIP module 32, two SWDs 44S instead of the chiplet 44C may be formed at the top surface of the first laminate substrate 36. One of the SWDs 44S is coupled to the second via structure 62-2, so as to be electrically coupled to the SMD 40S, while another one of the SWDs 44S is coupled to the third via structure 62-3, so as to be electrically coupled to the first bottom stilted interconnect 34-1. In some embodiments, both SMDs 44S may be thermally coupled to the second heatsink stanchion 60-2.

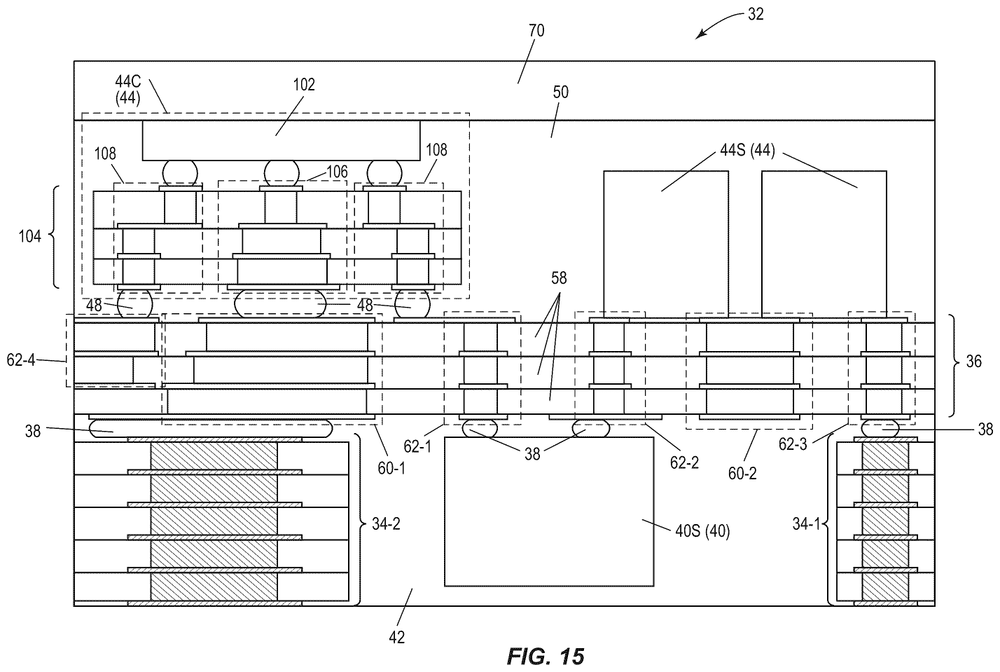

Alternatively, within the SIP module 32, the chiplet 44C instead of the wire-bond die 44W may be formed at the top surface of the first laminate substrate 36, and coupled to the second bottom stilted interconnect 34-2, as illustrated in FIG. 15. Herein, the first laminate substrate 36 may further include a fourth via structure 62-4, separate from the heatsink stanchions 60, and other via structures 62. The chip substrate 104 of the chiplet 44C is attached to the top surface of the first laminate substrate 36, where the chip heatsink stanchion 106 is coupled to the first heatsink stanchion 60-1 at the top surface of the first laminate substrate 36 through one second connecting element 48, one chip via structure 108 is coupled to the first via structure 62-1 at the top surface of the first laminate substrate 36 through one second connecting element 48, and the other chip via structure 108 is coupled to the fourth via structure 62-4 at the top surface of the first laminate substrate 36 through one second connecting element 48. As such, heat generated by the flip-chip die 102 can be dissipated downward through the chip heatsink stanchion 106 and the second bottom stilted interconnect 34-2, and can be dissipated upward directly through the heatsink spreader 70, thereby achieving dual-side cooling.

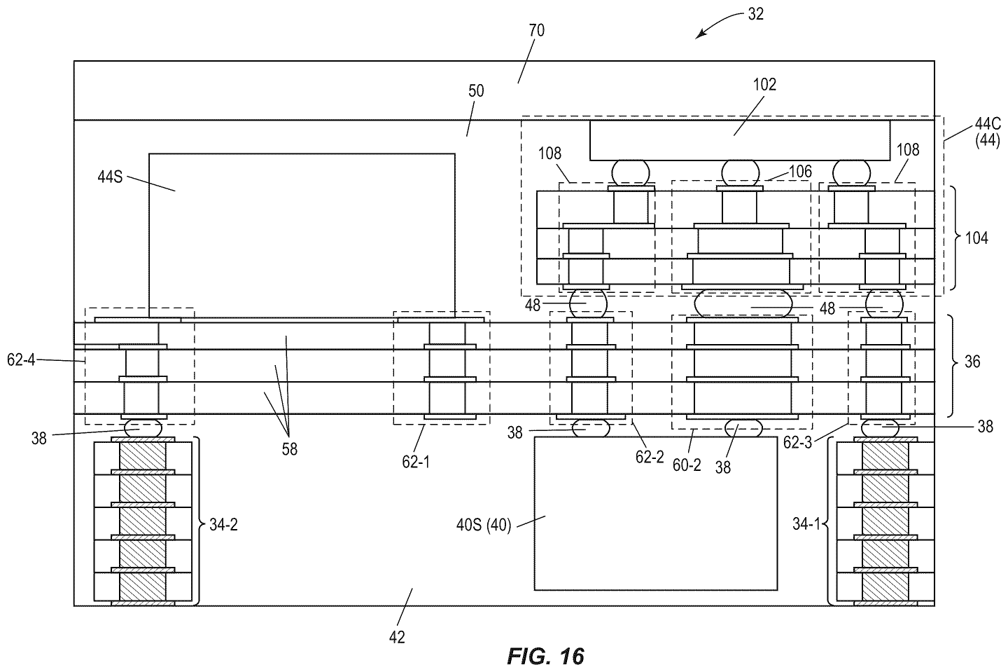

Alternatively, within the SIP module 32, the chiplet 44C and one large SMD 44S may be formed at the top surface of the first laminate substrate 36 (without a wire-bond die), as illustrated in FIG. 16. Herein, the first laminate substrate 36 may omit the first heatsink stanchion 60-1, and further include a fourth via structure 62-4, separate from the second heatsink stanchion 60-2, and other via structures 62. The SMD 44S is coupled to the first via structure 62-1 and the fourth via structure 62-4 at the top surface of the first laminate substrate 36. The second bottom stilted interconnect 34-2 is coupled to the fourth via structure 62-4 at the bottom surface of the first laminate substrate 36 through one first connecting element 38. As such, the SMD 44S is thermally and electrically connected to the second bottom stilted interconnect 34-2, and the second bottom stilted interconnect 34-2 can provide a signal and/or thermal path for the SMD 44S to a next level assembly (not shown).

In addition, in this illustration, the chiplet 44C is coupled to the second heatsink stanchion 60-2, the second via structure 62-2, and the third via structure 62-3 at the top surface of the first laminate substrate 36 through three second connecting elements 48, respectively. The SMD 40 is coupled to the second heatsink stanchion 60-2 and the second via structure 62-2 at the bottom surface of the first laminate substrate 36 through two first connecting elements 38, respectively. As such, the SMD 40S is thermally and electrically connected to the chiplet 44C. The first bottom stilted interconnect 34-1 is coupled to the third via structure 62-3 at the bottom surface of the first laminate substrate 36, the flip-chip die 102 of the chiplet 44C is connected to the first bottom stilted interconnect 34-1. The first bottom stilted interconnect 34-1 may serve as an I/O of the SIP module 32 and provide a signal path for the chiplet 44C to a next level assembly (not shown). In some embodiments, the first bottom stilted interconnect 34-1 may further provide a thermal path for the chiplet 44C and the SMD 40S.

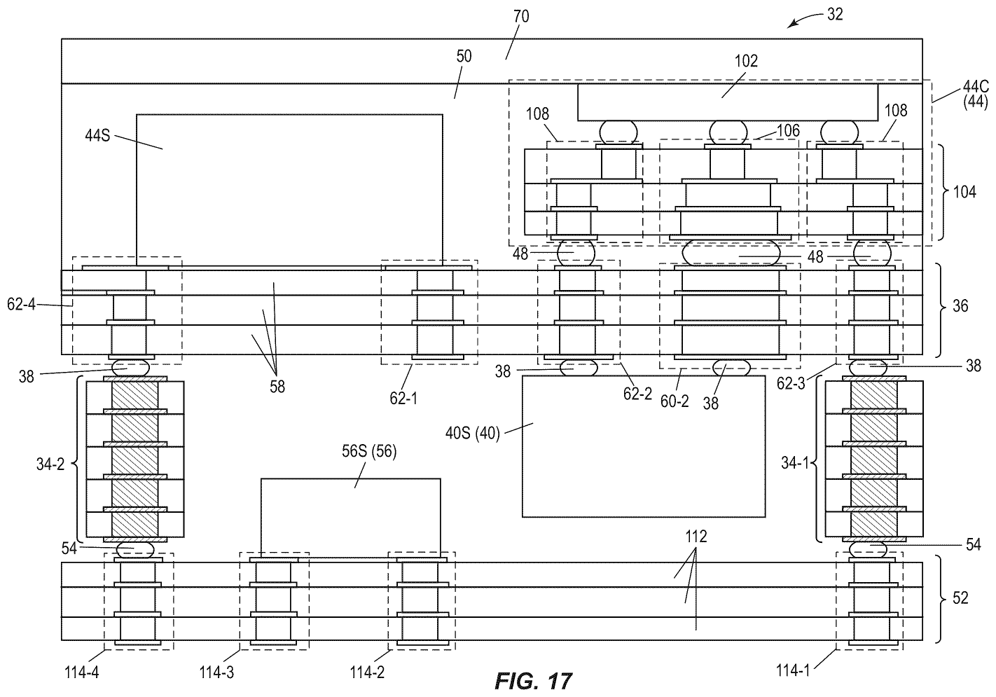

FIG. 17 shows a portion of the SIP module 32, which further includes a second laminate substrate 52 to accommodate more electronic components. The second laminate substrate 52 is located underneath the first laminate substrate 36 and connected to the first laminate substrate 36 through the stilted interconnects 34, which may also provide mechanical support between the first and second laminate substrates 36 and 52. In this illustration, the second laminate substrate 52 includes three dielectric layers 112 and four via structures 114 (e.g., a first via structure 114-1, a second via structure 114-2, a third via structure 114-3, and a fourth via structure 114-2) that extend vertically through the dielectric layers 112. One third electronic component 56 (e.g., an SMD 56S) is attached to the top surface of the second laminate substrate 52. In different applications, the second laminate substrate 52 may include fewer or more dielectric layers 112, and fewer or more via structures 114 with different connection configurations, and one or more heatsink stanchions (e.g., similar to the heatsink stanchions 60, not shown). The SIP module 32 may include more third electronic components 56 with different component types.

Herein, the first bottom stilted interconnect 34-1 is connected to the

first via structure 114-1 at the top surface of the second laminate substrate 52 through one third connecting element 54, and the second bottom stilted interconnect 34-2 is connected to the fourth via structure 114-4 at the top surface of the second laminate substrate 52 through one third connecting element 54. As such, a combination of the third via structure 62-3 in the first laminate substrate 36, the first bottom stilted interconnect 34-1, and the first via structure 114-1 in the second laminate substrate 52 provides a signal path (e.g., to a next level assembly) for the chiplet 44C. A combination of the fourth via structure 62-4 in the first laminate substrate 36, the second bottom stilted interconnect 34-2, and the fourth via structure 114-4 in the second laminate substrate 52 provides a signal path (e.g., to a next level assembly) for the SMD 44S. In addition, the SMD 56S is connected to the second and third via structures 114-2 and 114-3 at the top surface of the second laminate substrate 52.

Note that, the bottom stilted interconnects 34 with relatively large height may create a relatively large space vertically between the first and second laminate substrates 36 and 52. As such, large SMDs, especially large passive components can be accommodated within the SIP module 32. In some embodiments, the first electronic component(s) 40 (e.g., the SMD 40S), the bottom stilted interconnects 34, and the third electronic component(s) 56 (e.g., the SMD 56S) are exposed to air. In some embodiments, a mold compound (not shown) may fill gaps between the bottom surface of the first laminate substrate 36 and the top surface of the second laminate substrate 52 and encapsulate each first electronic component 40, each bottom stilted interconnect 34, and each third electronic component 56.

A SIP module enabling top-side and/or dual-side cooling and accommodating large surface mounted components, according to aspects disclosed herein, may be provided in or integrated into any processor-based electronics. Examples, without limitation, include a base station, a military application device, a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

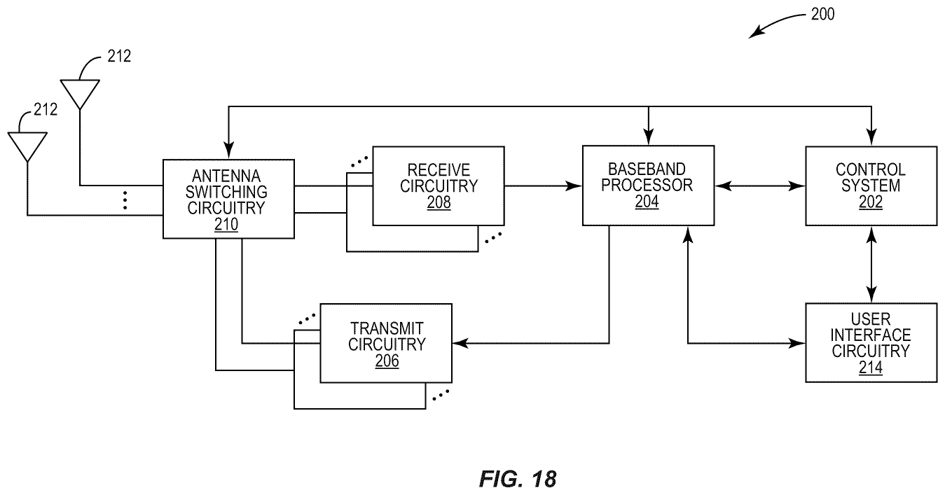

With reference to FIG. 18, the concepts described above may be implemented in various types of communication devices 200, such as those listed in the previous paragraph. The communication device 200 will generally include a control system 202, a baseband processor 204, transmit circuitry 206, receive circuitry 208, antenna switching circuitry 210, multiple antennas 212, and user interface circuitry 214. Herein, at least one or any combination of the control system 202, the baseband processor 204, the transmit circuitry 206, and the receive circuitry 208 may be implemented in the SIP module 32 (e.g. implemented in one or more of the first electronic components 40, the second electronic components 44, and/or the third electronic components 56) described above.

In a non-limiting example, the control system 202 can be a field-programmable gate array (FPGA) or an application-specific integrated circuit (ASIC), as an example. In this regard, the control system 202 can include at least a microprocessor(s), an embedded memory circuit(s), and a communication bus interface(s). The receive circuitry 208 receives radio frequency signals via the antennas 212 and through the antenna switching circuitry 210 from one or more base stations. A low noise amplifier and a filter of the receive circuitry 208 cooperate to amplify and remove broadband interference from the received signal for processing. Down conversion and digitization circuitry (not shown) will then down convert the filtered, received signal to an intermediate or baseband frequency signal, which is then digitized into one or more digital streams using an analog-to-digital converter(s) (ADC).

The baseband processor 204 processes the digitized received signal to extract the information or data bits conveyed in the received signal. This processing typically comprises demodulation, decoding, and error correction operations, as will be discussed in greater detail below. The baseband processor 204 is generally implemented in one or more digital signal processors (DSPs) and ASICs.

For transmission, the baseband processor 204 receives digitized data, which may represent voice, data, or control information, from the control system 202, which it encodes for transmission. The encoded data is output to the transmit circuitry 206, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 212 through the antenna switching circuitry 210. The multiple antennas 212 and the replicated transmit and receive circuitries 206, 208 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A system in package (SIP) module comprising:
a first laminate substrate;
at least one first electrical component formed at a bottom surface of the first laminate substrate; and
at least one bottom stilted interconnect connected to and protruding from the bottom surface of the first laminate substrate, wherein:
the at least one bottom stilted interconnect includes a plurality of dielectric sections and at least one conductive structure extending vertically through the plurality of dielectric sections;
each of the at least one conductive structure includes a plurality of conductors and a plurality of metal plates, wherein each of the plurality of conductors extends vertically through a corresponding one of the plurality of dielectric sections, and the plurality of metal plates alternate with the plurality of conductors in a vertical direction; and
the at least one first electrical component is at least electrically and/or thermally coupled to the at least one bottom stilted interconnect.

2. The SIP module of claim 1 wherein:
one of the plurality of dielectric sections includes a section protrusion, which extends horizontally beyond certain ones of the plurality of dielectric sections and has an exposed surface not covered by the certain ones of the plurality of dielectric sections;
one of the plurality of metal plates includes a plate protrusion that is formed on the exposed surface of the section protrusion; and
the at least one first electrical component is coupled to the at least one bottom stilted interconnect at the plate protrusion.

3. The SIP module of claim 1 wherein the at least one bottom stilted interconnect has a three-dimensional (3D) ring shape and is located about a periphery of the bottom surface of the first laminate substrate.

4. The SIP module of claim 3 wherein the at least one bottom stilted interconnect has a closed 3D ring shape.

5. The SIP module of claim 3 wherein the at least one bottom stilted interconnect has an open 3D ring shape with one or more openings, each of which extends vertically through the plurality of dielectric sections.

6. The SIP module of claim 1 wherein the at least one conductive structure comprises a plurality of conductive structures, each of which extends vertically through the plurality of dielectric sections.

7. The SIP module of claim 6 wherein the plurality of conductive structures is placed in a row or an array.

8. The SIP module of claim 1 wherein:
each of the plurality of conductors has a diameter between 50 μm and 1600 μm; and
a total height of the at least one bottom stilted interconnect is between 250 μm and 5000 μm.

9. The SIP module of claim 1 wherein the at least one bottom stilted interconnect further includes two spread conductive structures closely surrounding the at least one conductive structure, wherein:
each spread conductive structure extends vertically through the plurality of dielectric sections and is coupled to ground;
the at least one conductive structure is configured to transmit electrical signals; and
the two spread conductive structures are configured to maintain a characteristic impedance of the at least one conductive structure at a certain value.

10. The SIP module of claim 9 wherein:
the at least one conductive structure and the two spread conductive structures are configured to provide a first metal-plate pitch at a top side of the at least one bottom stilted interconnect, and a second metal-plate pitch at a bottom side of the at least one bottom stilted interconnect, wherein the first metal-plate pitch is finer than the second metal-plate pitch; and
the top side of the at least one bottom stilted interconnect faces the bottom surface of the first laminate substrate.

11. The SIP module of claim 1 wherein the at least one bottom stilted interconnect further includes one or more expanded conductive structures next to the at least one conductive structure, wherein:
each of the one or more expanded conductive structures extends vertically through the plurality of dielectric sections;
each of the one or more expanded conductive structures includes a plurality of conductors, each of which extends through a corresponding one of the plurality of dielectric sections, and a plurality of metal plates that alternate with the plurality of conductors in a vertical direction; and
the plurality of conductors within each of the one or more expanded conductive structures are not vertically aligned with each other, and a combination of the at least one conductive structure and the one or more expanded conductive structures provides different metal-plate pitches at the top side and the bottom side of the at least one bottom stilted interconnect.

12. The SIP module of claim 1 wherein the at least one first electrical component is one of a wire-bond die, a flip-chip die, a surface mounted device (SMD) and a chiplet.

13. The SIP module of claim 1 further includes a mold compound formed on the bottom surface of the first laminate substrate to at least encapsulate sides of the at least one first electronic component and to encapsulate sides of the at least one bottom stilted interconnect.

14. The SIP module of claim 1 wherein:
the first laminate substrate comprises a plurality of dielectric layers and at least one heatsink stanchion extending vertically through the plurality of dielectric layers; and
the at least one first electrical component is vertically aligned with and thermally coupled to the at least one heatsink stanchion, such that heat generated by the at least one first electrical component is eligible to be dissipated through the at least one heatsink stanchion to achieve top-side cooling.

15. The SIP module of claim 14 wherein the at least one bottom stilted interconnect is thermally coupled to the at least one first electrical component, such that the heat generated by the at least one first electrical component is eligible to be dissipated through both the at least one heatsink stanchion and the at least one bottom stilted interconnect to achieve dual-side cooling.

16. The SIP module of claim 14 further comprises a heatsink spreader over a top surface of the first laminate substrate and thermally coupled to the at least one heatsink stanchion.

17. The SIP module of claim 1 further includes at least one second electrical component formed on a top surface of the first laminate substrate, which is one of a wire-bond die, a flip-chip die, an SMD, and a chiplet.

18. The SIP module of claim 17 further includes at least one top stilted interconnect connected to the top surface of the first laminate substrate, wherein:
the at least one top stilted interconnect includes a plurality of dielectric sections and at least one conductive structure extending vertically through the plurality of dielectric sections of the at least one top stilted interconnect;
the at least one conductive structure of the at least one top stilted interconnect includes a plurality of conductors vertically aligned with each other and a plurality of metal plates, wherein each of the plurality of conductors extends vertically through a corresponding one of the plurality of dielectric sections, and the plurality of metal plates alternate with the plurality of conductors in a vertical direction; and
at least one of the at least one first electrical component and the at least one second electrical component is electrically and/or thermally coupled to the at least one top stilted interconnect.

19. The SIP module of claim 18 further includes a mold compound formed on the top surface of the first laminate substrate to at least encapsulate sides of the at least one second electronic component and to encapsulate sides of the at least one top stilted interconnect.

20. The SIP module of claim 1 further includes a second laminate substrate located underneath the first laminate substrate and connected to the first laminate substrate through the at least one bottom stilted interconnect.

21. The SIP module of claim 20 further includes at least one third electrical component formed on a top surface of the second laminate substrate, which is one of a wire-bond die, a flip-chip die, an SMD, and a chiplet.

22. A communication device comprising:
a control system;
a baseband processor;
receive circuitry; and
transmit circuitry, wherein at least one or any combination of the control system, the baseband processer, the transmit circuitry, and the receive circuitry is implemented in a SIP module, which includes a first laminate substrate, at least one first electrical component, and at least one bottom stilted interconnect, wherein:
the at least one first electrical component is formed at a bottom surface of the first laminate substrate;
the at least one bottom stilted interconnect is connected to and protrudes from the bottom surface of the first laminate substrate;
the at least one bottom stilted interconnect includes a plurality of dielectric sections and at least one conductive structure extending vertically through the plurality of dielectric sections;
each of the at least one conductive structure includes a plurality of conductors and a plurality of metal plates, wherein each of the plurality of conductors extends vertically through a corresponding one of the plurality of dielectric sections, and the plurality of metal plates alternate with the plurality of conductors in a vertical direction; and
the at least one first electrical component is at least electrically and/or thermally coupled to the at least one bottom stilted interconnect.
